(19) United States
(12) Patent Application Publication
(10) Pub. No.: US 2025/0201786 A1
(43) Pub. Date: Jun. 19, 2025

(54) PACKAGE COMPRISING INTEGRATED DEVICES AND A PASSIVE DEVICE

(71) Applicant: QUALCOMM Incorporated, San Diego, CA (US)

(72) Inventors: Yue LI, San Diego, CA (US); Ching-Liou HUANG, San Diego, CA (US); Ryan LANE, San Diego, CA (US); Charles David PAYNTER, Encinitas, CA (US); Piyush GUPTA, San Diego, CA (US)

(21) Appl. No.: 18/540,542

(22) Filed: Dec. 14, 2023

(51) Int. Cl. H01L 25/16; H01L 21/56; H01L 23/00; H01L 23/31; H01L 23/48; H01L 23/538

(52) U.S. Cl. CPC H01L 25/16; H01L 21/56; H01L 23/3157; H01L 23/481; H01L 23/5384; H01L 24/08; H01L 24/16; H01L 24/80; H01L 2224/08225; H01L 2224/16145; H01L 2224/80895; H01L 2224/80896

(57) ABSTRACT

A package comprising a first integrated device; an interposer coupled to the first integrated device; a passive device coupled to the first integrated device; a plurality of post interconnects coupled to the first integrated device; a second integrated device coupled to the interposer, the passive device and the plurality of post interconnects; and an encapsulation layer located between the first integrated device and the second integrated device.

### FIELD

Various features relate to packages with integrated devices.

### BACKGROUND

Packages can include various components including an integrated device. A package is There is an ongoing need to provide smaller packages with improved performances, such as packages with improved passive device performance and/or passive devices with reliable and robust joint connections in the package.

### SUMMARY

Various features relate to packages with integrated devices.

One example provides a package comprising a first integrated device; an interposer coupled to the first integrated device; a passive device coupled to the first integrated device; a plurality of post interconnects coupled to the first integrated device; a second integrated device coupled to the interposer, the passive device and the plurality of post interconnects; and an encapsulation layer located between the first integrated device and the second integrated device.

Another example provides a method for fabricating a package. The method provides a first integrated device. The method forms a first encapsulation layer that is coupled to the first integrated device. The method forms a first metallization portion that is coupled to the first integrated device. The method couples an interposer to the first metallization portion. The method couples a passive device to the first metallization portion. The method forms a plurality of post interconnects that are coupled to the first metallization portion. The method forms a second encapsulation layer that is coupled to the first metallization portion, the interposer, the passive device and the plurality of post interconnects. The method forms a second metallization portion that is coupled to the interposer, the passive device and the plurality of post interconnects. The method couples a second integrated device to the second metallization portion.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary profile view of a package with integrated devices and a deep trench capacitor device.

FIG. 2 illustrates an exemplary profile view of a package with integrated devices and a deep trench capacitor device.

FIG. 3 illustrates an exemplary profile view of a package with integrated devices and a deep trench capacitor device.

FIG. 4 illustrates an exemplary profile view of an integrated device.

FIG. 5 illustrates an exemplary profile view of a deep trench capacitor device.

FIGS. 6A-6D illustrate an exemplary sequence for fabricating a package with integrated devices and a deep trench capacitor device.

FIG. 7 illustrates an exemplary flow chart of a method for fabricating a package with integrated devices and a deep trench capacitor device.

FIGS. 8A-8D illustrate an exemplary sequence for fabricating a package with integrated devices and a deep trench capacitor device.

FIG. 9 illustrates an exemplary flow chart of a method for fabricating a package with integrated devices and a deep trench capacitor device.

FIGS. 10A-10B illustrate an exemplary sequence for fabricating a metallization portion.

FIG. 11 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a first integrated device; an interposer coupled to the first integrated device; a passive device coupled to the first integrated device; a plurality of post interconnects coupled to the first integrated device; a second integrated device coupled to the interposer, the passive device and the plurality of post interconnects; and an encapsulation layer located between the first integrated device and the second integrated device. The passive device is located between the first integrated device and the second integrated device. The passive device may include a deep trench capacitor device located between the first integrated device and the second integrated device. In some implementations, the position and/or location of the passive device between two integrated devices, helps provide improve power distribution to the first integrated device and/or the second integrated device, resulting in improved performances in the first integrated device and/or the second integrated device.

### Exemplary Package With Integrated Devices and a Passive Device

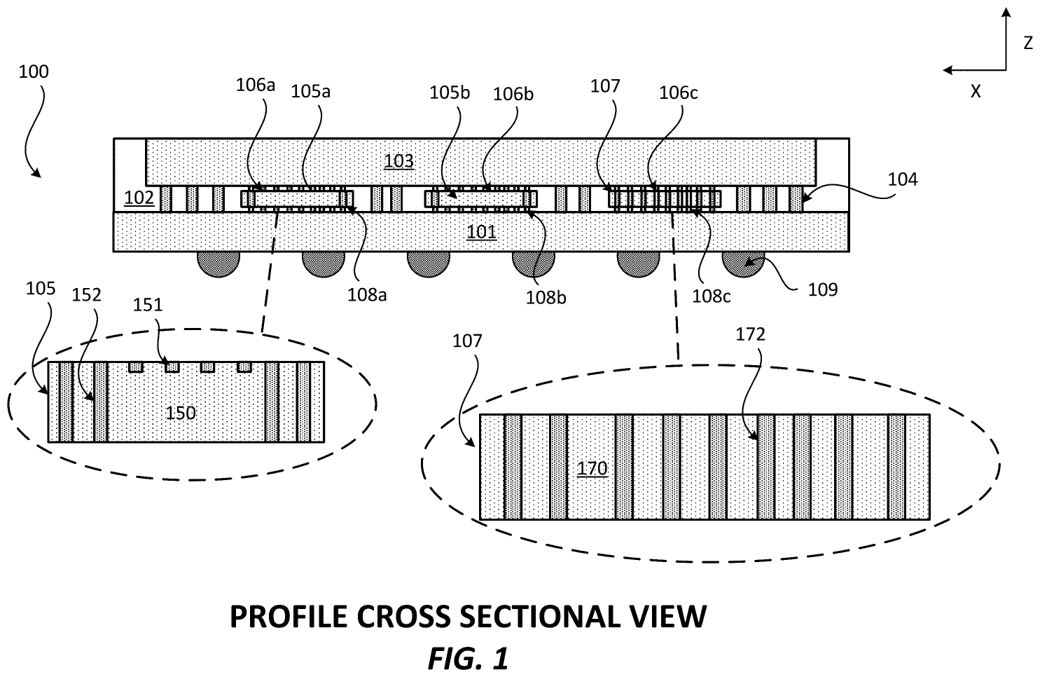

FIG. 1 illustrates a profile view of a package 100 that includes integrated devices and passive devices. The package 100 includes an integrated device 101, an encapsulation layer 102, an integrated device 103, a plurality of post interconnects 104, a plurality of passive devices 105, an interposer 107 and a plurality of solder interconnects 109. The plurality of passive devices 105 may include a passive device 105a (e.g., first passive device) and a passive device 105b (e.g., second passive device).

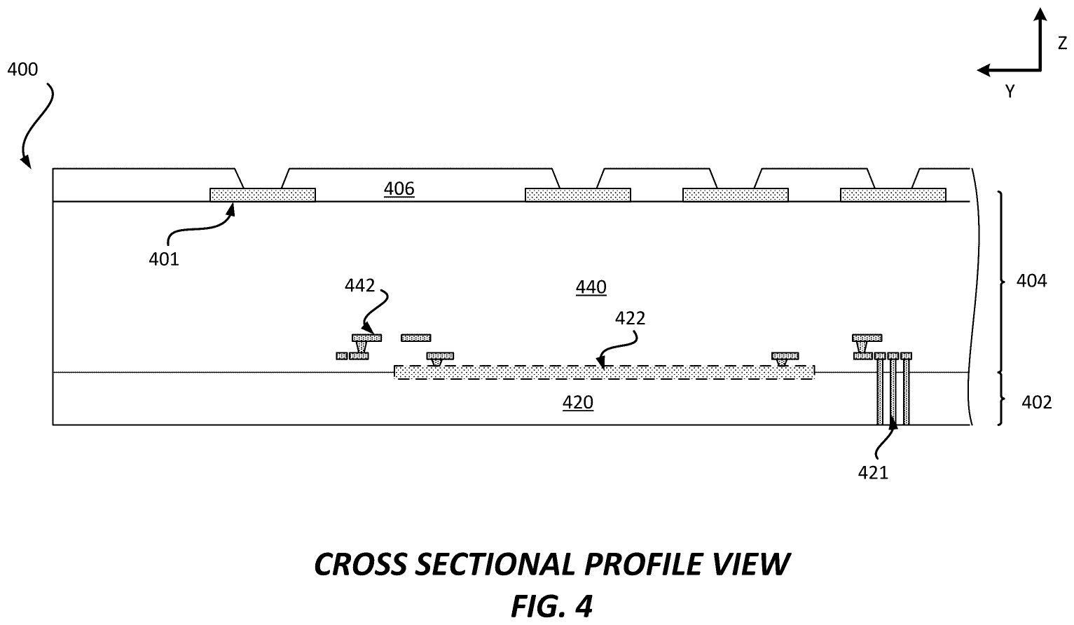

The integrated device 101 may be a first integrated device or a second integrated device. The integrated device 103 may be a first integrated device or a second integrated device. A more detailed example of the integrated device 101 and/or the integrated device 103 is described below in FIG. 4. The integrated device 101 may include a front side and a back side. The integrated device 103 may include a front side and a back side. The integrated device 101 and/or the integrated device 103 may include a die. The plurality of solder interconnects 109 may be coupled to the front side of the integrated device 101. The plurality of solder interconnects 109 may be coupled to pad interconnects of the integrated device 101.

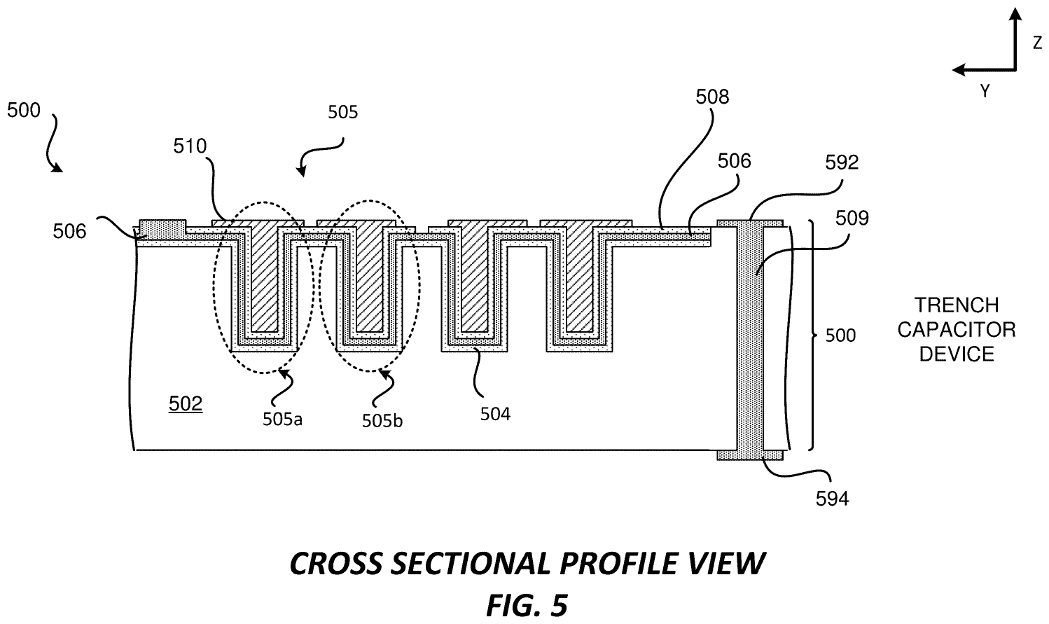

The passive device 105a and/or the passive device 105b may include a silicon capacitor, a deep trench capacitor (DTC) and/or a deep trench capacitor (DTC) device. A silicon capacitor may be a capacitor that is formed on a silicon substrate. For example, the passive device 105a may include a silicon substrate 150, a plurality of deep trench capacitors 151 and a plurality of through substrate vias 152. A more detailed example of a deep trench capacitor device is described below in FIG. 5.

The passive device 105a is coupled to the integrated device 101 and the integrated device 103. The passive device 105a may be coupled to the back side of the integrated device 101 through at least a plurality of solder interconnects 108a. For example, the plurality of solder interconnects 108a may be coupled to the plurality of through substrate vias (e.g., 152) of the passive device 105a. The plurality of solder interconnects 108a may be coupled to the plurality of through substrate vias of the integrated device 101. The passive device 105a may be coupled to the front side of the integrated device 101 through at least a plurality of solder interconnects 106a.

The passive device 105a may have a front side and a back side. The front side of the passive device 105a may be the side that includes the deep trench capacitors. The back side of the passive device 105a may be opposite to the front side of the passive device 105a. The front side of the passive device 105a may face and/or point in the direction of the integrated device 103. In some implementations, the front side of the passive device 105a may face and/or point in the direction of the integrated device 101. In some implementations, the front side of the passive device 105a may be closer to the integrated device 101 than the back side of the passive device 105a is to the integrated device 101.

The passive device 105b is coupled to the integrated device 101 and the integrated device 103. The passive device 105b is coupled to the back side of the integrated device 101 through at least a plurality of solder interconnects 108b. For example, the plurality of solder interconnects 108b may be coupled to the plurality of through substrate vias (e.g., 152) of the passive device 105b. The plurality of solder interconnects 108b may be coupled to the plurality of through substrate vias of the integrated device 101. The passive device 105b may be coupled to the front side of the integrated device 103 through at least a plurality of solder interconnects 106b.

The passive device 105b may have a front side and a back side. The front side of the passive device 105b may be the side that includes the deep trench capacitors. The back side of the passive device 105b may be opposite to the front side of the passive device 105b. The front side of the passive device 105b may face and/or point in the direction of the integrated device 103. In some implementations, the front side of the passive device 105b may face and/or point in the direction of the integrated device 101. In some implementations, the front side of the passive device 105b may be closer to the integrated device 101 than the back side of the passive device 105b is to the integrated device 101.

The plurality of post interconnects 104 are coupled to the integrated device 101 and the integrated device 103. The plurality of post interconnects 104 may be located between the integrated device 101 and the integrated device 103. The plurality of post interconnects 104 may be located between the back side of the integrated device 101 and the front side of the integrated device 103. Thus, the plurality of post interconnects 104 may be coupled to (i) the back side of the integrated device 101 and (ii) the front side of the integrated device 103. The plurality of post interconnects 104 may or may not touch (i) the back side of the integrated device 101 and (ii) the front side of the integrated device 103. In some implementations, solder interconnects may be used to couple the plurality of post interconnects 104 to the integrated device 101 and/or the integrated device 103. For example, a first plurality of solder interconnects may be used to couple the plurality of post interconnects 104 to the integrated device 101, and/or a second plurality of solder interconnects may be used to couple the plurality of post interconnects 104 to the integrated device 103.

The interposer 107 is located between the integrated device 101 and the integrated device 103. The interposer 107 may include a silicon substrate 170 and a plurality of interposer interconnects 172. The plurality of interposer interconnects 172 may include through substrate vias. The interposer 107 is coupled to the integrated device 101 and the integrated device 103. The interposer 107 may be coupled to the back side of the integrated device 101 through a plurality of solder interconnects 108c. The interposer 107 may be coupled to the front side of the integrated device 103 through a plurality of solder interconnects 106c. The pitch of the plurality of interposer interconnects 172 of the interposer 107 may be smaller than the pitch of the plurality of post interconnects 104.

The encapsulation layer 102 is located between the integrated device 101 and the integrated device 103. The encapsulation layer 102 may touch the back side of the integrated device 101 and the front side of the integrated device 103. The encapsulation layer 102 may at least partially encapsulate the passive device 105a, the passive device 105b, the interposer 107 and the plurality of post interconnects 104. The encapsulation layer 102 may at least partially encapsulate the integrated device 103. The encapsulation layer 102 may include a mold, a resin and/or an epoxy. The encapsulation layer 102 may be a means for encapsulation. The encapsulation layer 102 may be provided by using a compression and transfer molding process, a sheet molding process, or a liquid molding process.

Providing the passive device 105a and/or the passive device 105b between two integrated devices provides several advantages. One, providing the passive devices between two integrated devices helps improve the power distribution network performance, since the passive devices are closer to the integrated device 101 and/or the integrated device 103. In some implementations, the power distribution network performance of the integrated device 103 is greatly improved due to the passive devices being very close to the front side of the integrated device 103. Moreover, the position and/or location of the passive devices helps avoid large loop inductance between the circuit and the power source. Two, the position and/or location of the passive devices and/or interposer helps avoid having top integrated device offset for the package to accommodate the interconnects for power, thus keeping the package more compact or as compact as possible.

An electrical path between the integrated device 101 and the integrated device 103 may include components from the integrated device 101, the passive device 105a and/or components from the integrated device 103. An electrical path between the integrated device 101 and the integrated device 103 may include components from the integrated device 101, the interposer 107 and/or components from the integrated device 103. An electrical path between the integrated device 101 and the integrated device 103 may include components from the integrated device 101, the plurality of post interconnects 104 and/or components from the integrated device 103. Examples of components for an integrated device that may be part of an electrical path are further described below in at least FIG. 4.

FIG. 1 illustrates that the lateral size of the integrated device 101 is greater than the lateral size of the integrated device 103. For example, a width of the integrated device 101 may be greater than a width of the integrated device 103. However, in some implementations, the integrated device 101 may have a lateral size that is similar or smaller than a lateral size of the integrated device 103.

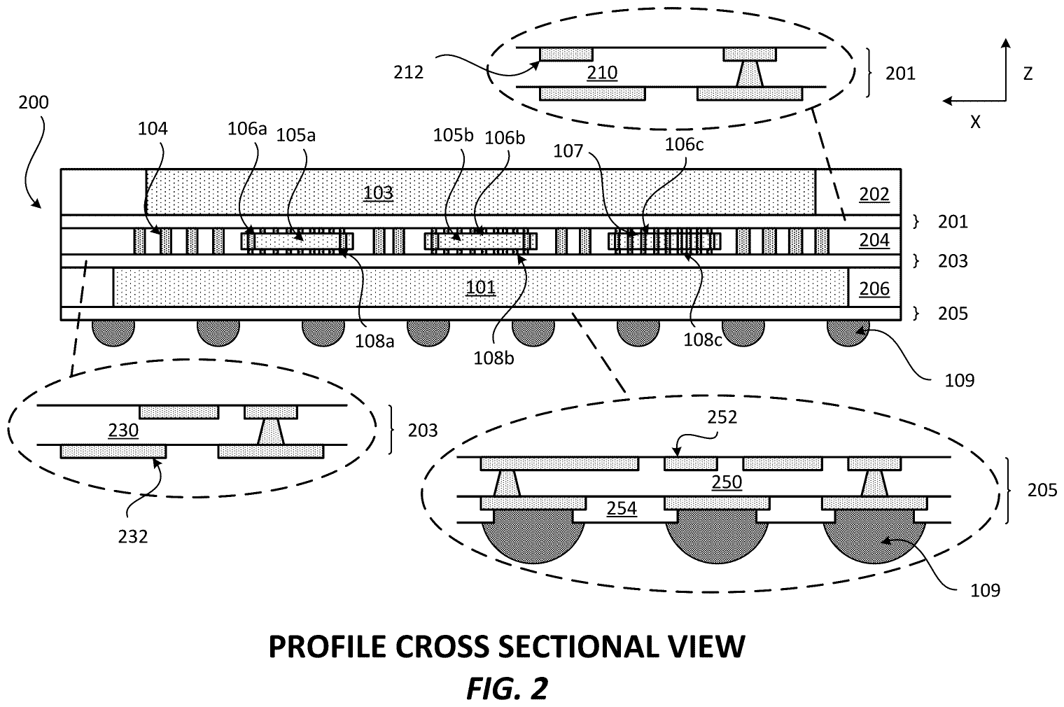

FIG. 2 illustrates a profile view of a package 200 that includes integrated devices and passive devices. The package 200 includes an integrated device 101, an integrated device 103, a plurality of post interconnects 104, a plurality of passive devices 105, an interposer 107, a plurality of solder interconnects 109, a metallization portion 201, a metallization portion 203, a metallization portion 205, an encapsulation layer 202, an encapsulation layer 204 and an encapsulation layer 206. The plurality of passive devices 105 may include a passive device 105a (e.g., first passive device) and a passive device 105b (e.g., second passive device).

The package 200 is similar to the package 100 of FIG. 1 and provides similar technical advantages. However, the package 200 includes metallization portions between some of the components. Any of the metallization portions (e.g., 201, 203, 205) may be the first metallization portion, the second metallization portion or the third metallization portion. Different implementations may have different number of metallization portions and each metallization portions may have different or similar number of metal layers. Thus, the metallization portion 201, the metallization portion 203 and/or the metallization portion 205 are all optional. A metallization portion may be a redistribution portion. FIG. 2 is described with all 3 metallization portions included in the package 200. However, any of the metallization portions may be optional and may be removed.

The front side of the integrated device 101 may be coupled to and touching the metallization portion 205. The metallization portion 205 may include at least one dielectric layer 250, a plurality of metallization interconnects 252 and a solder resist layer 254. The metallization portion 205 may include a redistribution portion. The plurality of metallization interconnects 252 may include a plurality of redistribution interconnects. The plurality of metallization interconnects 252 may be coupled to pad interconnects of the integrated device 101. The plurality of solder interconnects 109 are coupled to the metallization portion 205. For example, the plurality of solder interconnects 109 are coupled to the plurality of metallization interconnects 252.

The metallization portion 203 is coupled to and touching the back side of the integrated device 101. The metallization portion 203 may include at least one dielectric layer 230 and a plurality of metallization interconnects 232. The metallization portion 203 may include a redistribution portion. The plurality of metallization interconnects 232 may include a plurality of redistribution interconnects. The plurality of metallization interconnects 232 may be coupled to through substrate vias of the integrated device 101. The encapsulation layer 206 is coupled to and touching the integrated device 101, the metallization portion 203 and the metallization portion 205. The encapsulation layer 206 and the integrated device 101 are located between the metallization portion 203 and the metallization portion 205.

The metallization portion 201 may include at least one dielectric layer 210 and a plurality of metallization interconnects 212. The metallization portion 201 may include a redistribution portion. The plurality of metallization interconnects 212 may include a plurality of redistribution interconnects.

The passive device 105a is coupled to the metallization portion 203 through a plurality of solder interconnects 108a. The plurality of solder interconnects 108a may be coupled to the plurality of metallization interconnects 232 of the metallization portion 203. The passive device 105a is coupled to the metallization portion 201 through a plurality of solder interconnects 106a. The plurality of solder interconnects 106a may be coupled to the plurality of metallization interconnects 212 of the metallization portion 201. The passive device 105b is coupled to the metallization portion 203 through a plurality of solder interconnects 108b. The plurality of solder interconnects 108b may be coupled to the plurality of metallization interconnects 232 of the metallization portion 203. The passive device 105b is coupled to the metallization portion 201 through a plurality of solder interconnects 106b. The plurality of solder interconnects 106b may be coupled to the plurality of metallization interconnects 212 of the metallization portion 201. The interposer 107 is coupled to the metallization portion 203 through a plurality of solder interconnects 108c. The plurality of solder interconnects 108c may be coupled to the plurality of metallization interconnects 232 of the metallization portion 203. The interposer 107 is coupled to the metallization portion 201 through a plurality of solder interconnects 106c. The plurality of solder interconnects 106c may be coupled to the plurality of metallization interconnects 212 of the metallization portion 201. The plurality of post interconnects 104 is coupled to the metallization portion 201 and the metallization portion 203. The plurality of post interconnects 104 may be coupled to the plurality of metallization interconnects 212 and/or the plurality of metallization interconnects 232. In some implementations, solder interconnects may be used to couple the plurality of post interconnects 104 to the metallization portion 201 and/or the metallization portion 203. For example, a first plurality of solder interconnects may be used to couple the plurality of post interconnects 104 to metallization interconnects of the metallization portion 201, and/or a second plurality of solder interconnects may be used to couple the plurality of post interconnects 104 to metallization interconnects of the metallization portion 203.

The encapsulation layer 204 may be coupled to and touching the metallization portion 201, the metallization portion 203, the plurality of post interconnects 104, the passive device 105a, the passive device 105b and the interposer 107. The encapsulation layer 204, the plurality of post interconnects 104, the passive device 105a, the passive device 105b, the interposer 107 are located between the metallization portion 201 and the metallization portion 203.

The integrated device 103 is coupled to the metallization portion 201. For example, the front side of the integrated device 103 may be coupled to and touching the metallization portion 201. The plurality of metallization interconnects 212 may be coupled to pad interconnects of the integrated device 103. The encapsulation layer 202 is coupled to and touching the metallization portion 201 and the integrated device 103. The encapsulation layer 102 may include a mold, a resin and/or an epoxy. Any of the encapsulation layer (e.g., 202, 204, 206) may be a means for encapsulation. An encapsulation layer may be provided by using a compression and transfer molding process, a sheet molding process, or a liquid molding process. Any of the encapsulation layers (e.g., 202, 204, 206) may be a first encapsulation layer, a second encapsulation layer and/or a third encapsulation layer.

An electrical path between the integrated device 101 and the integrated device 103 may include components from the integrated device 101, the metallization portion 203, the passive device 105a, the metallization portion 201, and/or components from the integrated device 103. An electrical path between the integrated device 101 and the integrated device 103 may include components from the integrated device 101, the metallization portion 203, the interposer 107, the metallization portion 201, and/or components from the integrated device 103. An electrical path between the integrated device 101 and the integrated device 103 may include components from the integrated device 101, the metallization portion 203, the plurality of post interconnects 104, the metallization portion 201, and/or components from the integrated device 103. An electrical path between the integrated device 103 and the plurality of solder interconnects 109 may include components from the integrated device 101, the metallization portion 201, the passive device 105a, the passive device 105b, the interposer 107, the plurality of post interconnects 104, the metallization portion 203, components from the integrated device 103 and/or the metallization portion 205. Examples of components for an integrated device that may be part of an electrical path are further described below in at least FIG. 4.

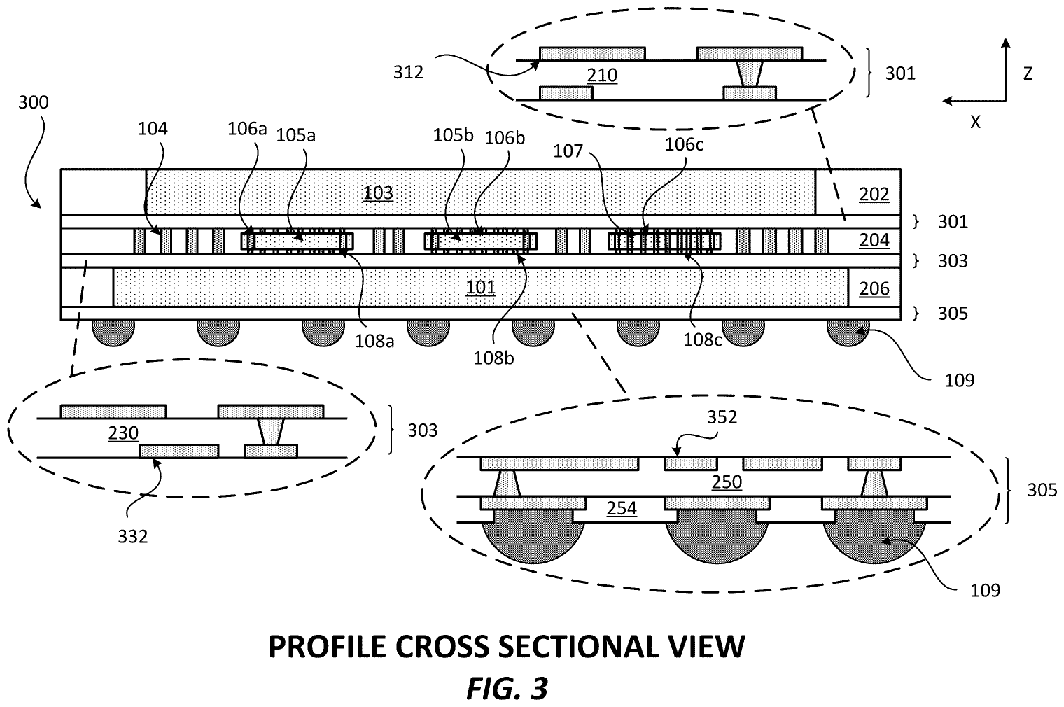

FIG. 3 illustrates a profile view of a package 300 that includes integrated devices and passive devices. The package 300 includes an integrated device 101, an integrated device 103, a plurality of post interconnects 104, a plurality of passive devices 105, an interposer 107, a plurality of solder interconnects 109, a metallization portion 301, a metallization portion 303, a metallization portion 305, an encapsulation layer 202, an encapsulation layer 204 and an encapsulation layer 206. The plurality of passive devices 105 may include a passive device 105a (e.g., first passive device) and a passive device 105b (e.g., second passive device).

The package 300 is similar to the package 200 of FIG. 2 and provides similar technical advantages. However, the package 300 includes metallization portions that may be formed and/or fabricated differently. In some implementations, the sequence for fabricating the metallization portions may be different from how the metallization portions in the package 200 are fabricated. Any of the metallization portions (e.g., 301, 303, 305) may be the first metallization portion, the second metallization portion or the third metallization portion. Different implementations may have different number of metallization portions and each metallization portions may have different or similar number of metal layers. Thus, the metallization portion 301, the metallization portion 303 and/or the metallization portion 305 are all optional. A metallization portion may be a redistribution portion. FIG. 3 is described with all 3 metallization portions included in the package 200. However, any of the metallization portion may be removed.

The front side of the integrated device 101 may be coupled to and touching the metallization portion 305. The metallization portion 305 may include at least one dielectric layer 250, a plurality of metallization interconnects 352 and a solder resist layer 254. The metallization portion 305 may include a redistribution portion. The plurality of metallization interconnects 352 may include a plurality of redistribution interconnects. The plurality of metallization interconnects 352 may be coupled to and touching pad interconnects of the integrated device 101. The plurality of solder interconnects 109 are coupled to the metallization portion 305. For example, the plurality of solder interconnects 109 are coupled to the plurality of metallization interconnects 352.

The metallization portion 303 may be coupled to and touching the back side of the integrated device 101. The metallization portion 303 may include at least one dielectric layer 230 and a plurality of metallization interconnects 332. The metallization portion 303 may include a redistribution portion. The plurality of metallization interconnects 332 may include a plurality of redistribution interconnects. The plurality of metallization interconnects 332 may be coupled to and touching the plurality of through substrate vias of the integrated device 101. The encapsulation layer 206 is coupled to and touching the integrated device 101, the metallization portion 303 and the metallization portion 305. The encapsulation layer 206 and the integrated device 101 are located between the metallization portion 303 and the metallization portion 305.

The metallization portion 301 may include at least one dielectric layer 210 and a plurality of metallization interconnects 312. The metallization portion 301 may include a redistribution portion. The plurality of metallization interconnects 312 may include a plurality of redistribution interconnects.

The passive device 105a is coupled to the metallization portion 303 through a plurality of solder interconnects 108a. The plurality of solder interconnects 108a may be coupled to the plurality of metallization interconnects 332 of the metallization portion 303. The passive device 105a is coupled to the metallization portion 301 through a plurality of solder interconnects 106a. The plurality of solder interconnects 106a may be coupled to the plurality of metallization interconnects 312 of the metallization portion 301. The passive device 105b is coupled to the metallization portion 303 through a plurality of solder interconnects 108b. The plurality of solder interconnects 108b may be coupled to the plurality of metallization interconnects 332 of the metallization portion 303. The passive device 105b is coupled to the metallization portion 301 through a plurality of solder interconnects 106b. The plurality of solder interconnects 106b may be coupled to the plurality of metallization interconnects 312 of the metallization portion 301. The interposer 107 is coupled to the metallization portion 303 through a plurality of solder interconnects 108c. The plurality of solder interconnects 108c may be coupled to the plurality of metallization interconnects 332 of the metallization portion 303. The interposer 107 is coupled to the metallization portion 301 through a plurality of solder interconnects 106c. The plurality of solder interconnects 106c may be coupled to the plurality of metallization interconnects 312 of the metallization portion 301. The plurality of post interconnects 104 is coupled to the metallization portion 301 and the metallization portion 303. The plurality of post interconnects 104 may be coupled to the plurality of metallization interconnects 312 and/or the plurality of metallization interconnects 332. In some implementations, solder interconnects may be used to couple the plurality of post interconnects 104 to the metallization portion 301 and/or the metallization portion 303. For example, a first plurality of solder interconnects may be used to couple the plurality of post interconnects 104 to metallization interconnects of the metallization portion 301, and/or a second plurality of solder interconnects may be used to couple the plurality of post interconnects 104 to metallization interconnects of the metallization portion 303.

The encapsulation layer 204 is coupled to and touching the metallization portion 301, the metallization portion 303, the plurality of post interconnects 104, the passive device 105a, the passive device 105b and the interposer 107. The encapsulation layer 204, the plurality of post interconnects 104, the passive device 105a, the passive device 105b, the interposer 107 are located between the metallization portion 301 and the metallization portion 303. The encapsulation layer 204 may at least partially encapsulate the plurality of post interconnects 104, the passive device 105a, the passive device 105b and/or the interposer 107.

The integrated device 103 is coupled to the metallization portion 301. For example, the front side of the integrated device 103 is coupled to the metallization portion 301. The encapsulation layer 202 is coupled to and touching the metallization portion 301 and the integrated device 103. The encapsulation layer 102 may include a mold, a resin and/or an epoxy. Any of the encapsulation layer (e.g., 202, 204, 206) may be a means for encapsulation. An encapsulation layer may be provided by using a compression and transfer molding process, a sheet molding process, or a liquid molding process. Any of the encapsulation layers (e.g., 202, 204, 206) may be a first encapsulation layer, a second encapsulation layer and/or a third encapsulation layer.

An electrical path between the integrated device 101 and the integrated device 103 may include components from the integrated device 101, the metallization portion 303, the passive device 105a, the metallization portion 301, and/or components from the integrated device 103. An electrical path between the integrated device 101 and the integrated device 103 may include components from the integrated device 101, the metallization portion 303, the interposer 107, the metallization portion 301, and/or components from the integrated device 103. An electrical path between the integrated device 101 and the integrated device 103 may include components from the integrated device 101, the metallization portion 303, the plurality of post interconnects 104, the metallization portion 301, and/or components from the integrated device 103. An electrical path between the integrated device 103 and the plurality of solder interconnects 109 may include components from the integrated device 101, the metallization portion 301, the passive device 105a, the passive device 105b, the interposer 107, the plurality of post interconnects 104, the metallization portion 303, components from the integrated device 103 and/or the metallization portion 305. Examples of components for an integrated device that may be part of an electrical path are further described below in at least FIG. 4.

For the electrical paths described in the disclosure, if one or more solder interconnects are used to electrically couple interconnects from two components, such solder interconnects may be part of one or more electrical paths between the two components. An electrical path that includes a particular a metallization portion may include metallization interconnects from that particular metallization portion. An electrical path that includes a particular a passive device may include interconnects from that particular passive device. An electrical path that includes an interposer may include interconnects from the interposer.

### Exemplary Integrated Device

FIG. 4 illustrates a cross sectional profile view of an integrated device 400 that includes a die substrate. The integrated device 400 may represent the integrated device 101 and/or the integrated device 103. The integrated device 400 includes a die substrate portion 402 and a die interconnection portion 404. The die substrate portion 402 includes a die substrate 420, an active region 422 and a plurality of through substrate vias 421. The active region 422 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 422 of the die substrate 420.

The die substrate 420 may include silicon (Si). The die substrate 420 may comprise a bulk silicon. The plurality of through substrate vias 421 extend through the die substrate 420. A plurality of pad interconnects (not shown) may be coupled to the plurality of through substrate vias 421. The plurality of pad interconnects may be formed on the back side of the die substrate 420.

The die interconnection portion 404 includes at least one dielectric layer 440 and a plurality of die interconnects 442. The die interconnection portion 404 is coupled to the die substrate portion 402. The plurality of die interconnects 442 is coupled to the active region 422 of the die substrate portion 402. The plurality of die interconnects 442 may be coupled to the plurality of through substrate vias 421. The die interconnection portion 404 may also include a plurality of pad interconnects 401 and a passivation layer 406. In some implementations, a back end of line (BEOL) process may be used to fabricate the die interconnection portion 404. A plurality of pad interconnects 401 may be coupled to the plurality of die interconnects 442. A passivation layer 406 may be formed and coupled to the die interconnection portion 404.

A front side of the integrated device 400 may include the side that comprises the plurality of pad interconnects 401. A component that is coupled to a front side of the integrated device (e.g., 400) may mean that the component is coupled to and touching the plurality of pad interconnects 401. In some implementations, an integrated device may include additional metallization interconnects that are coupled to the plurality of pad interconnects 401. In such instances, when a component is coupled to the front side of the integrated device, the component may be coupled to and touching the additional metallization interconnects coupled to the plurality of pad interconnects 401. In some implementations, the component may be coupled to the front side of the integrated device through a plurality of solder interconnects and/or a plurality of pillar interconnects.

A back side of the integrated device 400 may include the side that comprises the die substrate 420. A component that is coupled to a back side of the integrated device (e.g., 400) may mean that the component is coupled to and touching the plurality of through substrate vias 421 of the integrated device. In some implementations, an integrated device may include additional metallization interconnects (e.g., pad interconnects) that are coupled to the plurality of through substrate vias 421. In such instances, when a component is coupled to the back side of the integrated device, the component may be coupled to and touching the additional metallization interconnects coupled to the plurality of through substrate vias 421. In some implementations, the component may be coupled to the back side of the integrated device through a plurality of solder interconnects and/or a plurality of pillar interconnects.

In some implementations, an electrical path to and/or from an active region 422 may include at least one die interconnect from the plurality of die interconnects 442, at least one through substrate via from the plurality of through substrate vias 421. In some implementations, an electrical path to and/or from an active region 422 may include at least one die interconnect from the plurality of die interconnects 442 and at least one pad interconnect from the plurality of pad interconnects 401. An electrical path through the integrated device 400 may include the plurality of through substrate vias 421, a plurality of die interconnects 442, and/or a plurality of pad interconnects 401. An electrical path through the integrated device 400 may include the plurality of through substrate vias 421, a plurality of die interconnects 442, an active region 422 and/or a plurality of pad interconnects 401.

An integrated device (e.g., 101, 103, 400) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 100) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advance technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

### Exemplary Passive Device

Different implementations may provide different types of passive device. In some implementations, the passive device may include an integrated passive device (IPD). In some implementations, the passive device may include a deep trench capacitor (e.g., trench capacitor device). In some implementations, the passive device is implemented as a passive chiplet.

FIG. 5 illustrates a cross sectional profile view of a passive device 500 that is configured as a trench capacitor device. The passive device 500 may be an integrated passive device that includes multiple trench capacitors (e.g., deep trench capacitors). The passive device 500 may be a means for trench capacitance. The passive device 500 may represent the passive device 105a and/or the passive device 105b. The passive device 500 includes a front side and a back side. The front side of the passive device 500 may include the side that comprises the plurality of trench capacitors. The back side of the passive device 500 may be opposite to the front side of the passive device 500. Although not shown in FIG. 5, the passive device 500 may include a polyimide layer (e.g., 115) coupled to a surface (e.g., front side surface) of the passive device 500.

The passive device 500 includes a passive device substrate 502 and a plurality of trench capacitors 505. A plurality of solder interconnects (not shown) may be coupled to the passive device 500. The passive device substrate 502 may include silicon (Si). The passive device substrate 502 may include a plurality of trenches and/or cavities over which capacitors may be formed.

The plurality of trench capacitors 505 include a trench capacitor 505a and a trench capacitor 505b. The trench capacitor 505a and the trench capacitor 505b may be configured to be part of a same capacitor (e.g., first capacitor, first trench capacitor). The trench capacitor 505a and the trench capacitor 505b may be configured to be coupled to and/or part of a first power distribution network (PDN). The trench capacitor 505a and the trench capacitor 505b may be configured to be part of a first electrical path for a first power for a package. The trench capacitor 505a and the trench capacitor 505b may be configured to be coupled to integrated device(s).

As shown in FIG. 5, the passive device 500 includes the passive device substrate 502, an oxide layer 504, a first electrically conductive layer 506, a dielectric layer 508, and a second electrically conductive layer 510. The first electrically conductive layer 506 and/or the second electrically conductive layer 510 may include polysilicon. The oxide layer 504 and/or the dielectric layer 508 may include SiO₂ (e.g., low-pressure chemical vapor deposition (LPCVD) SiO₂) or Si₃N₄ (e.g., LPCVD Si₃N₄). Portions of the oxide layer 504, the first electrically conductive layer 506, the dielectric layer 508, and the second electrically conductive layer 510 may be located in trenches and/or cavities of the passive device substrate 502. It is noted that a passive device substrate 502 may be considered to have a trench or a cavity, even if the trench or the cavity is filled with one or more materials.

The trench capacitor 505a (e.g., first trench capacitor, first capacitor, means for first trench capacitance) may be defined by (i) a first portion of the oxide layer 504, (ii) a first portion of the first electrically conductive layer 506, (iii) a first portion of the dielectric layer 508, and (iv) a first portion of the second electrically conductive layer 510 that are located in a trench (e.g., first trench) of the passive device substrate 502.

The trench capacitor 505b (e.g., second trench capacitor, second capacitor, means for second trench capacitance) may be defined by (i) a second portion of the oxide layer 504, (ii) a second portion of the first electrically conductive layer 506, (iii) a second portion of the dielectric layer 508, and (iv) a second portion of the second electrically conductive layer 510 that are located in a trench (e.g., second trench) of the passive device substrate 502. It is noted that trench capacitor 505b may be part of a same capacitor as the trench capacitor 505a. That is, the trench capacitor 505a and the trench capacitor 505b may be configured to be electrically coupled together to form a capacitor (e.g., first capacitor) with a greater capacitance.

As mentioned above, the passive device 500 may include a polyimide layer 115 that is coupled to a front side of the passive device 500. The front side of the passive device 500 may be a side that includes the trench capacitors.

As mentioned above, a metallization portion (e.g., 201, 203, 205, 301, 303, 305) may include a redistribution portion that includes redistribution interconnects (e.g., redistribution layer (RDL) interconnects). A redistribution interconnect may include portions that have a U-shape or V-shape. The terms “U-shape” and “V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect).

### Exemplary Sequence for Fabricating a Package Comprising Integrated Devices and a Passive Device

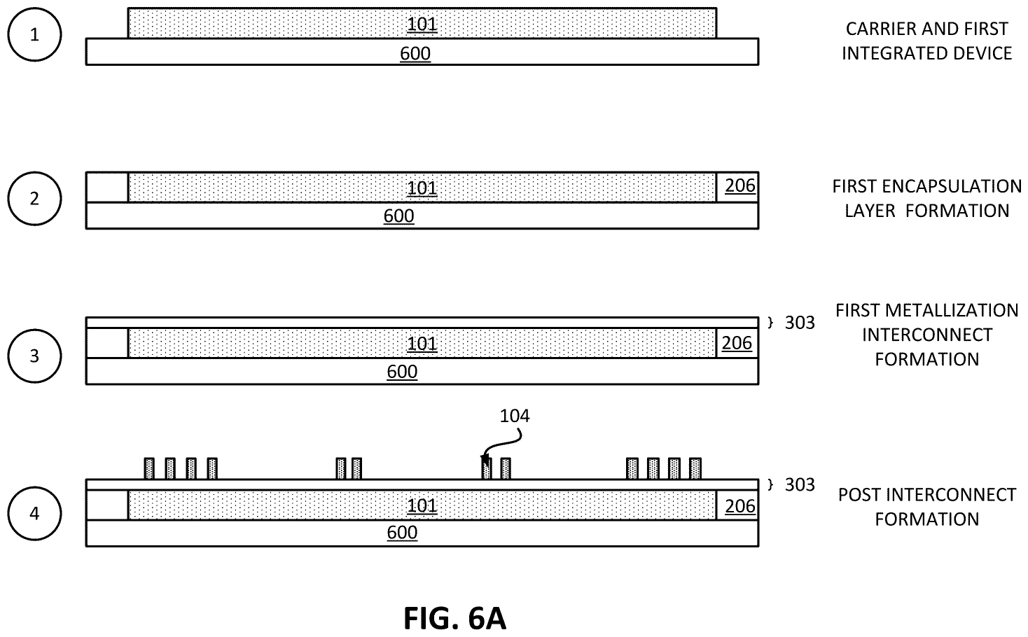

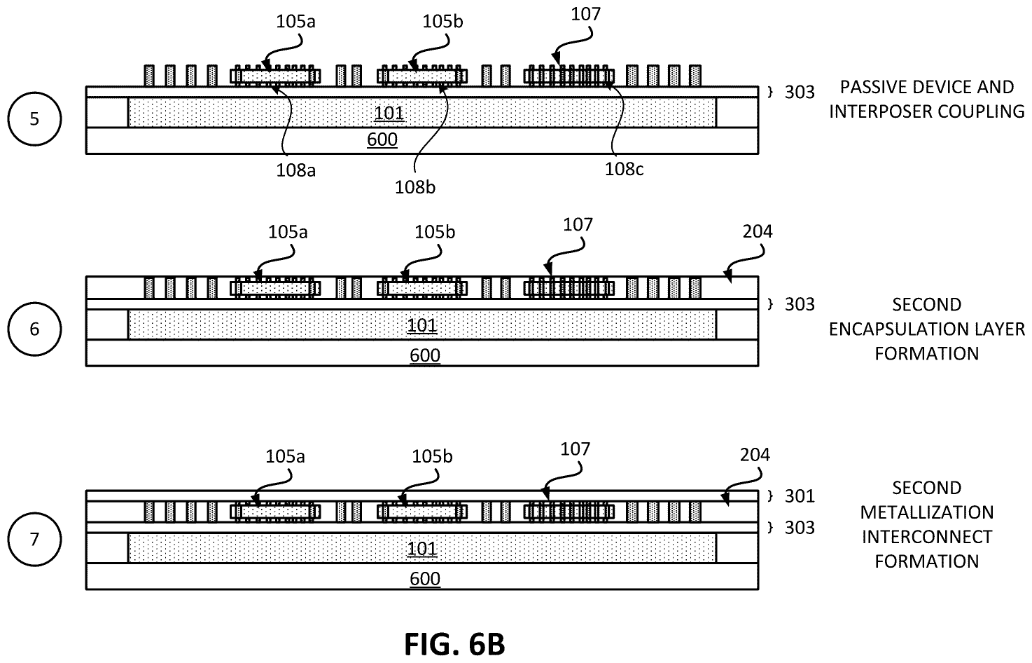

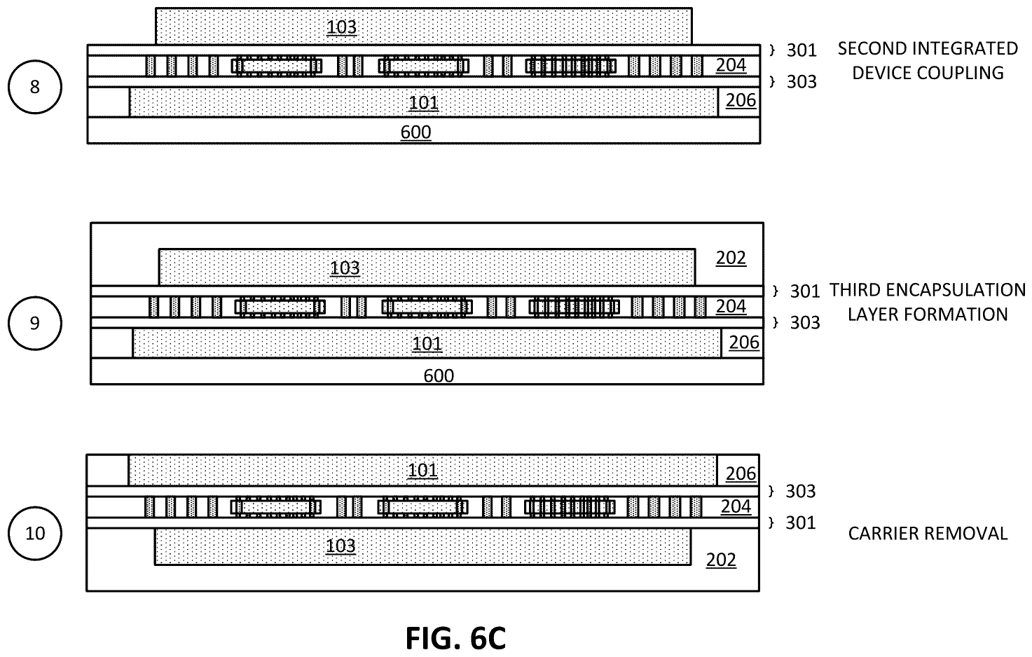

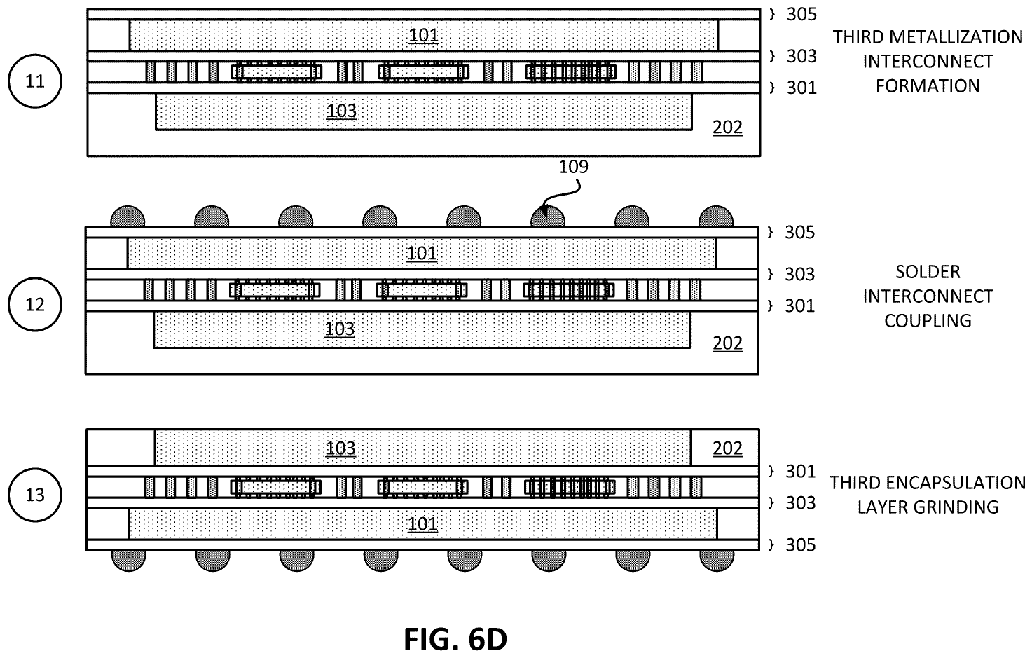

FIGS. 6A-6D illustrate an exemplary sequence for providing or fabricating a package with integrated devices and a passive device. In some implementations, the sequence of FIGS. 6A-6D may be used to provide or fabricate any of the packages described in the disclosure. In some implementations, the sequence of FIGS. 6A-6D may be used to provide or fabricate the package 300 described in the disclosure.

It should be noted that the sequence of FIGS. 6A-6D may combine one or more stages in order to simplify and/or clarify the sequence for providing or fabricating a package. In some implementations, the order of the processes may be changed or modified. In some implementations, one or more of processes may be replaced or substituted without departing from the spirit of the disclosure. Different implementations may fabricate a package differently.

Stage 1, as shown in FIG. 6A, illustrates a state after an integrated device 101 and a carrier 600 are provided. The integrated device 101 may be placed and coupled to the carrier 600 through an adhesive (not shown). The front side of the integrated device 101 may be coupled to the carrier 600. The carrier 600 may include tape.

Stage 2 illustrates a state after an encapsulation layer 206 is formed over the carrier 600. The encapsulation layer 206 may be coupled to the carrier and the integrated device 101. The encapsulation layer 206 may be formed over the back side of the integrated device 101 and portions of the encapsulation layer 206 may be removed (e.g., grinded off, polished). In some implementations, portions of the integrated device 101 may also be removed (e.g., grinded off). For example, the back side of the integrated device 101 may be removed. In one example, a die substrate of the integrated device 101 may be removed and/or thinned. Portions of the through substrate vias of the integrated device 101 may be exposed. The encapsulation layer 206 may be provided by using a compression and transfer molding process, a sheet molding process, or a liquid molding process.

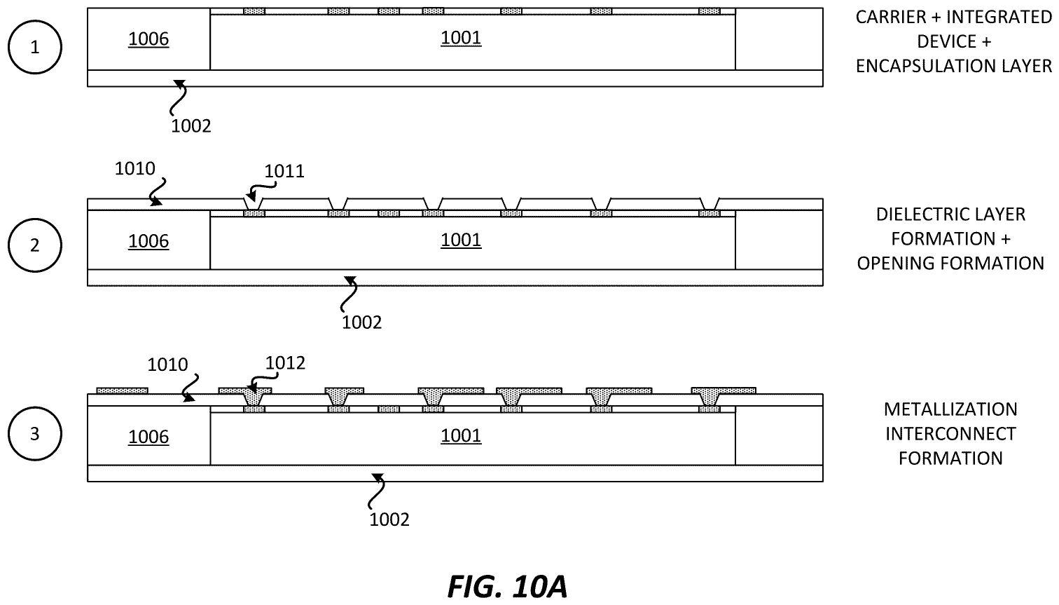

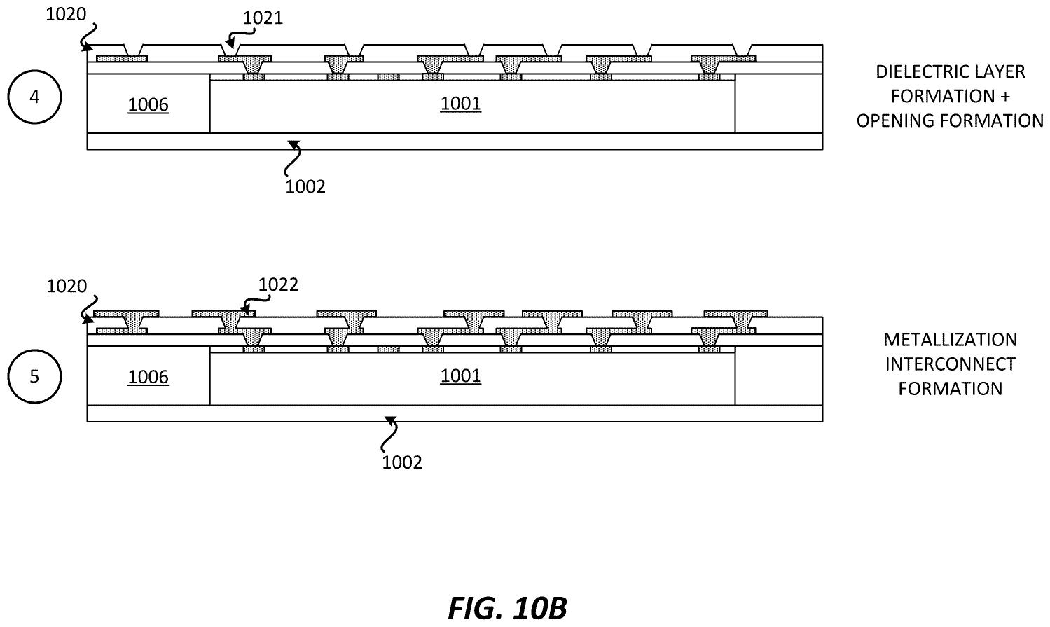

Stage 3 illustrates a state after a metallization portion 303 is formed and coupled to the back side of the integrated device 101. The metallization portion 303 may include at least one dielectric layer 230 and a plurality of metallization interconnects 332. The metallization portion 303 may include a redistribution portion. The plurality of metallization interconnects 332 may include a plurality of redistribution interconnects. The metallization portion 303 may touch the back side of the integrated device 101. The plurality of metallization interconnects 332 may be coupled to the plurality of through substrate vias of the integrated device 101. A lamination process and a plating process may be used to form the metallization portion 303. An example of fabricating a metallization portion is described below in at least FIGS. 10A-10B.

Stage 4 illustrates a state after a plurality of post interconnects 104 are formed and coupled to the metallization portion 303. The plurality of post interconnects 104 may be coupled to and touching the plurality of metallization interconnects 332. A plating process may be used to form the plurality of post interconnects 140. In the event there is no metallization portion 303, the plurality of post interconnects 104 may be formed and coupled to the back side of the integrated device 101.

Stage 5, as shown in FIG. 6B, illustrates a state after the passive device 105a, the passive device 105b, and the interposer 107 are placed and coupled to the metallization portion 303. The passive device 105a may be coupled to the metallization portion 303 through a plurality of solder interconnects 108a, using a solder reflow process. The passive device 105b may be coupled to the metallization portion 303 through a plurality of solder interconnects 108b, using a solder reflow process. The interposer 107 may be coupled to the metallization portion 303 through a plurality of solder interconnects 108c, using a solder reflow process. In the event there is no metallization portion 303, the passive device 105a, the passive device 105b and/or the interposer 107 may be coupled to the back side of the integrated device 101.

Stage 6 illustrates a state after an encapsulation layer 204 is formed over the metallization portion 303. The encapsulation layer 204 may be coupled to the metallization portion 303. The encapsulation layer 204 may be formed over the passive device 105a, the passive device 105b, the interposer 107 and the plurality of post interconnects 104 and portions of the encapsulation layer 204 may be removed (e.g., grinded off, polished). In some implementations, portions of the passive device 105a, portions of the passive device 105b, portions of the interposer 107 and/or portions of the plurality of post interconnects 104 may also be removed (e.g., grinded off). The encapsulation layer 204 may be provided by using a compression and transfer molding process, a sheet molding process, or a liquid molding process.

Stage 7 illustrates a state after a metallization portion 301 is formed and coupled to the passive device 105a, the passive device 105b, the interposer 107 and/or the plurality of post interconnects 104. The metallization portion 301 may include at least one dielectric layer 210 and a plurality of metallization interconnects 312. The metallization portion 301 may include a redistribution portion. The plurality of metallization interconnects 312 may include a plurality of redistribution interconnects. The metallization portion 301 may touch the passive device 105a, the passive device 105b, the interposer 107 and/or the plurality of post interconnects 104. There may or may not be solder interconnects between (i) the metallization portion 301 and (ii) the passive device 105a, the passive device 105b, the interposer 107 and/or the plurality of post interconnects 104. A lamination process and a plating process may be used to form the metallization portion 301. An example of fabricating a metallization portion is described below in at least FIGS. 10A-10B.

Stage 8, as shown in FIG. 6C, illustrates a state after the integrated device 103 is placed and coupled to the metallization portion 301. A solder reflow process may be used to couple the integrated device 103 to the metallization portion 301 through at least a plurality of solder interconnects (not shown). The plurality of solder interconnects may be coupled to the plurality of pad interconnects of the integrated device 103 and the plurality of metallization interconnects 312 of the metallization portion 301. The front side of the integrated device 103 may face and/or point in the direction of the surface of the metallization portion 301. In some implementations, the front side of the integrated device 103 may be closer to the metallization portion 301 than the back side of the integrated device 103 is to the metallization portion 301.

In some implementations, the integrated device 103 is coupled to the metallization portion 301 through at least a plurality of pillar interconnects and a plurality of solder interconnects (not shown). In the event there is no metallization portion 301, the integrated device 103 may be coupled to the passive device 105a, the passive device 105b, the interposer 107 and the plurality of post interconnects 104 through a plurality of solder interconnects, using a solder reflow process.

Stage 9 illustrates a state after an encapsulation layer 202 is formed over the metallization portion 301 and the integrated device 103. The encapsulation layer 202 may be coupled to the metallization portion 301 and the integrated device 103. The encapsulation layer 202 may be provided by using a compression and transfer molding process, a sheet molding process, or a liquid molding process.

Stage 10 illustrates a state after the carrier 600 is decoupled from the integrated device 101 and the encapsulation layer 206. The carrier 600 may be detached and/or removed from the integrated device 101 and/or the encapsulation layer 206.

Stage 11, as shown in FIG. 6D, illustrates a state after a metallization portion 305 is formed and coupled to the front side of the integrated device 101. The metallization portion 305 may include at least one dielectric layer 250 and a plurality of metallization interconnects 352. The metallization portion 305 may include a redistribution portion. The plurality of metallization interconnects 352 may include a plurality of redistribution interconnects. The metallization portion 305 may touch the front side of the integrated device 101. The plurality of metallization interconnects 352 may be coupled to the plurality of pad interconnects of the integrated device 101. A lamination process and a plating process may be used to form the metallization portion 305. An example of fabricating a metallization portion is described below in at least FIGS. 10A-10B.

Stage 12 illustrates a state after the plurality of solder interconnects 109 are coupled to the metallization portion 305. A solder reflow process may be used to couple the plurality of solder interconnects 109 to the plurality of metallization interconnects 352 of the metallization portion 305. In the event there is no metallization portion 305, the plurality of solder interconnects 109 may be coupled to the integrated device 101 (e.g., front side of the integrated device 101), using a solder reflow process.

Stage 13 illustrates a state after a portion of the encapsulation layer 202 is removed (e.g., thinned, grinded off, polished). The process of removing a portion of the encapsulation layer 202 may also remove a portion of the integrated device 103. For example, a portion of the back side of the integrated device 103 may be removed, where a portion of the die substrate of the integrated device 103 is removed and/or thinned. Stage 13 illustrates an example of the package 300.

### Exemplary Flow Diagram of a Method for Fabricating a Package Comprising Integrated Devices and a Passive Device

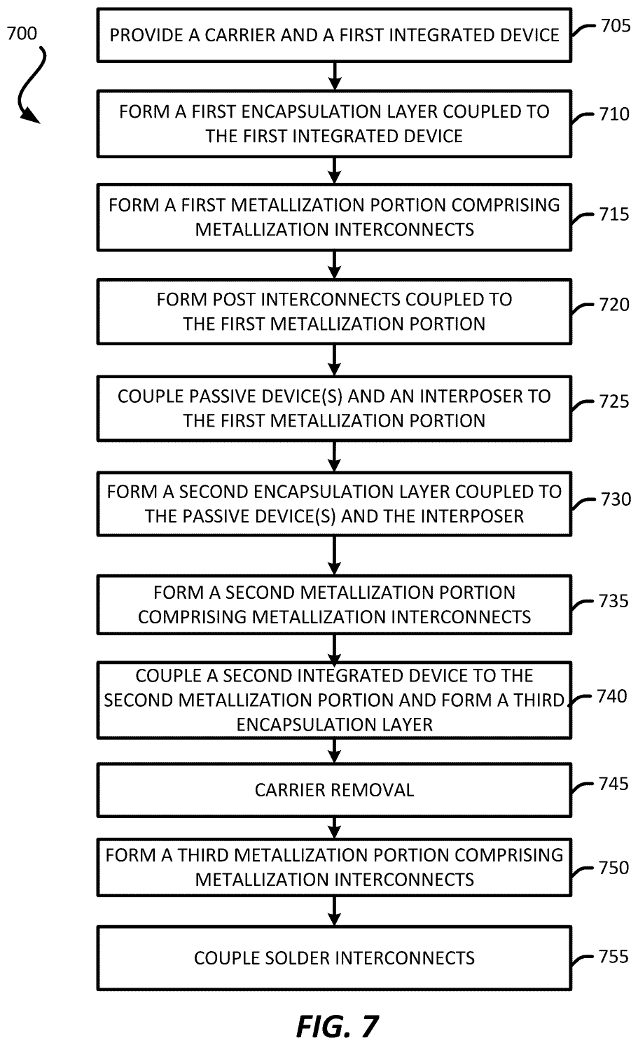

In some implementations, fabricating a package includes several processes. FIG. 7 illustrates an exemplary flow diagram of a method 700 for providing or fabricating a package with integrated devices and a passive device. In some implementations, the method 700 of FIG. 7 may be used to provide or fabricate the package 300.

It should be noted that the method 700 of FIG. 7 may combine one or more stages and/or sequences in order to simplify and/or clarify the method for providing or fabricating a package. In some implementations, the order of the processes may be changed or modified. In some implementations, one or more of processes may be replaced or substituted without departing from the spirit of the disclosure. Different implementations may fabricate a package differently.

The method provides (at 705) a carrier and a first integrated device. Stage 1 of FIG. 6A, illustrates and describes an example of a state after an integrated device 101 and a carrier 600 are provided. The integrated device 101 may be placed and coupled to the carrier 600 through an adhesive (not shown). The front side of the integrated device 101 may be coupled to the carrier 600. The carrier 600 may include tape.

The method forms (at 710) a first encapsulation layer that is coupled to the first integrated device. Stage 2 of FIG. 6A, illustrates and describes an example of a state after an encapsulation layer 206 is formed over the carrier 600. The encapsulation layer 206 may be coupled to the carrier and the integrated device 101. The encapsulation layer 206 may be formed over the back side of the integrated device 101 and portions of the encapsulation layer 206 may be removed (e.g., grinded off, polished). In some implementations, portions of the integrated device 101 may also be removed (e.g., grinded off). For example, the back side of the integrated device 101 may be removed. In one example, a die substrate of the integrated device 101 may be removed and/or thinned. Portions of the through substrate vias of the integrated device 101 may be exposed. The encapsulation layer 206 may be provided by using a compression and transfer molding process, a sheet molding process, or a liquid molding process.

The method forms (at 715) a first metallization portion that comprises a plurality of metallization interconnects. Stage 3 of FIG. 6A, illustrates and describes an example of a state after a metallization portion 303 is formed and coupled to the back side of the integrated device 101. The metallization portion 303 may include at least one dielectric layer 230 and a plurality of metallization interconnects 332. The metallization portion 303 may include a redistribution portion. The plurality of metallization interconnects 332 may include a plurality of redistribution interconnects. The metallization portion 303 may touch the back side of the integrated device 101. The plurality of metallization interconnects 332 may be coupled to the plurality of through substrate vias of the integrated device 101. A lamination process and a plating process may be used to form the metallization portion 303. An example of fabricating a metallization portion is described below in at least FIGS. 10A-10B.

The method forms (at 720) a plurality of post interconnects. The plurality of post interconnects may be coupled to a metallization portion. Stage 4 of FIG. 6A, illustrates and describes an example of a state after a plurality of post interconnects 104 are formed and coupled to the metallization portion 303. The plurality of post interconnects 104 may be coupled to and touching the plurality of metallization interconnects 332. A plating process may be used to form the plurality of post interconnects 140. In the event there is no metallization portion 303, the plurality of post interconnects 104 may be formed and coupled to the back side of the integrated device 101.

The method places and couples (at 725) at least one passive device and an interposer to the metallization portion. Stage 5 of FIG. 6B, illustrates and describes an example of a state after the passive device 105a, the passive device 105b, and the interposer 107 are placed and coupled to the metallization portion 303. The passive device 105a may be coupled to the metallization portion 303 through a plurality of solder interconnects 108a, using a solder reflow process. The passive device 105b may be coupled to the metallization portion 303 through a plurality of solder interconnects 108b, using a solder reflow process. The interposer 107 may be coupled to the metallization portion 303 through a plurality of solder interconnects 108c, using a solder reflow process. In the event there is no metallization portion 303, the passive device 105a, the passive device 105b and/or the interposer 107 may be coupled to the back side of the integrated device 101.

The method forms (at 730) a second encapsulation that is coupled to the passive devices, the interposer and the plurality of post interconnects. Stage 6 of FIG. 6B, illustrates and describes an example of a state after an encapsulation layer 204 is formed over the metallization portion 303. The encapsulation layer 204 may be coupled to the metallization portion 303. The encapsulation layer 204 may be formed over the passive device 105a, the passive device 105b, the interposer 107 and the plurality of post interconnects 104 and portions of the encapsulation layer 204 may be removed (e.g., grinded off, polished). In some implementations, portions of the passive device 105a, portions of the passive device 105b, portions of the interposer 107 and/or portions of the plurality of post interconnects 104 may also be removed (e.g., grinded off). The encapsulation layer 204 may be provided by using a compression and transfer molding process, a sheet molding process, or a liquid molding process.

The method forms (at 735) a second metallization portion. Stage 7 of FIG. 6B, illustrates and describes an example of a state after a metallization portion 301 is formed and coupled to the passive device 105a, the passive device 105b, the interposer 107 and/or the plurality of post interconnects 104. The metallization portion 301 may include at least one dielectric layer 210 and a plurality of metallization interconnects 312. The metallization portion 301 may include a redistribution portion. The plurality of metallization interconnects 312 may include a plurality of redistribution interconnects. The metallization portion 301 may touch the passive device 105a, the passive device 105b, the interposer 107 and/or the plurality of post interconnects 104. There may or may not be solder interconnects between (i) the metallization portion 301 and (ii) the passive device 105a, the passive device 105b, the interposer 107 and/or the plurality of post interconnects 104. A lamination process and a plating process may be used to form the metallization portion 301. An example of fabricating a metallization portion is described below in at least FIGS. 10A-10B.

The method couples (at 740) a second integrated device to the second metallization portion and forms a third encapsulation layer. Stages 8 and 9 of FIG. 6C, illustrates an example of coupling a second integrated device to the second metallization portion and forming a third encapsulation layer.

Stage 8 of FIG. 6C, illustrates and describes an example of a state after the integrated device 103 is placed and coupled to the metallization portion 301. A solder reflow process may be used to couple the integrated device 103 to the metallization portion 301 through at least a plurality of solder interconnects (not shown). The plurality of solder interconnects may be coupled to the plurality of pad interconnects of the integrated device 103 and the plurality of metallization interconnects 312 of the metallization portion 301. The front side of the integrated device 103 may face and/or point in the direction of the surface of the metallization portion 301. In some implementations, the front side of the integrated device 103 may be closer to the metallization portion 301 than the back side of the integrated device 103 is to the metallization portion 301. In some implementations, the integrated device 103 is coupled to the metallization portion 301 through at least a plurality of pillar interconnects and a plurality of solder interconnects (not shown). In the event there is no metallization portion 301, the integrated device 103 may be coupled to the passive device 105a, the passive device 105b, the interposer 107 and the plurality of post interconnects 104 through a plurality of solder interconnects, using a solder reflow process.

Stage 9 of FIG. 6C, illustrates and describes an example of a state after an encapsulation layer 202 is formed over the metallization portion 301 and the integrated device 103. The encapsulation layer 202 may be coupled to the metallization portion 301 and the integrated device 103. The encapsulation layer 202 may be provided by using a compression and transfer molding process, a sheet molding process, or a liquid molding process.

The method decouples (at 745) the carrier. Stage 10 of FIG. 6C, illustrates and describes an example of a state after the carrier 600 is decoupled from the integrated device 101 and the encapsulation layer 206. The carrier 600 may be detached and/or removed from the integrated device 101 and/or the encapsulation layer 206.

The method forms (at 750) a third metallization portion. Stage 11 of FIG. 6D, illustrates and describes an example of a state after a metallization portion 305 is formed and coupled to the front side of the integrated device 101. The metallization portion 305 may include at least one dielectric layer 250 and a plurality of metallization interconnects 352. The metallization portion 305 may include a redistribution portion. The plurality of metallization interconnects 352 may include a plurality of redistribution interconnects. The metallization portion 305 may touch the front side of the integrated device 101. The plurality of metallization interconnects 352 may be coupled to the plurality of pad interconnects of the integrated device 101. A lamination process and a plating process may be used to form the metallization portion 305. An example of fabricating a metallization portion is described below in at least FIGS. 10A-10B.

The method couples (at 755) the plurality of solder interconnects to the third metallization portion. Stage 12 of FIG. 6D, illustrates and describes an example of a state after the plurality of solder interconnects 109 are coupled to the metallization portion 305. A solder reflow process may be used to couple the plurality of solder interconnects 109 to the plurality of metallization interconnects 352 of the metallization portion 305. In the event there is no metallization portion 305, the plurality of solder interconnects 109 may be coupled to the integrated device 101, using a solder reflow process.

In some implementations, the method may remove portions of the third encapsulation layer. Removing portions of the third encapsulation layer may occur before or after the plurality of solder interconnects are coupled to the third metallization portion, as described at stage 12 of FIG. 6D. Stage 13 of FIG. 6D, illustrates and describes an example of a state after a portion of the encapsulation layer 202 is removed (e.g., thinned, grinded off, polished). The process of removing a portion of the encapsulation layer 202 may also remove a portion of the integrated device 103. For example, a portion of the back side of the integrated device 103 may be removed, where a portion of the die substrate of the integrated device 103 is removed and/or thinned. Stage 13 of FIG. 6D, illustrates an example of the package 300.

It is noted that the use and/or labeling of the first integrated device and the second integrated device is arbitrary. Any of the integrated devices may be the first integrated device and/or the second integrated device. It is noted that the use and/or labeling of the first metallization portion, the second metallization portion and the third metallization portion is arbitrary. Any of the metallization portions may be the first metallization portion, the second metallization portion and/or the third metallization portion. It is noted that the use and/or labeling of the first encapsulation layer, the second encapsulation layer and the third encapsulation layer is arbitrary. Any of the encapsulation layers may be the first encapsulation layer, the second encapsulation layer and/or the third encapsulation layer.

### Exemplary Sequence for Fabricating a Package Comprising Integrated Devices and a Passive Device

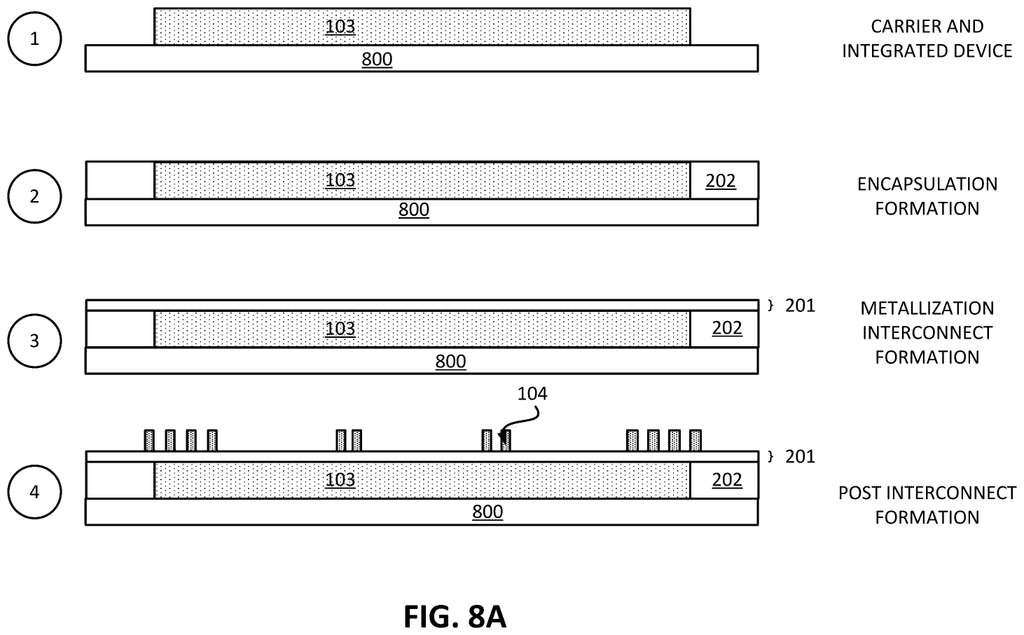

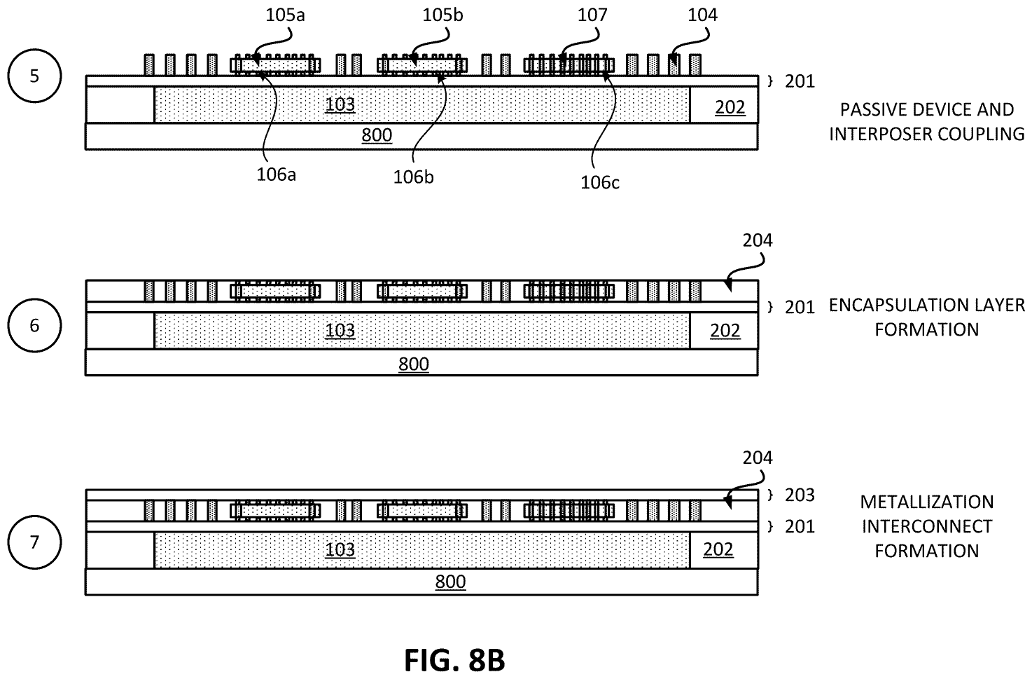

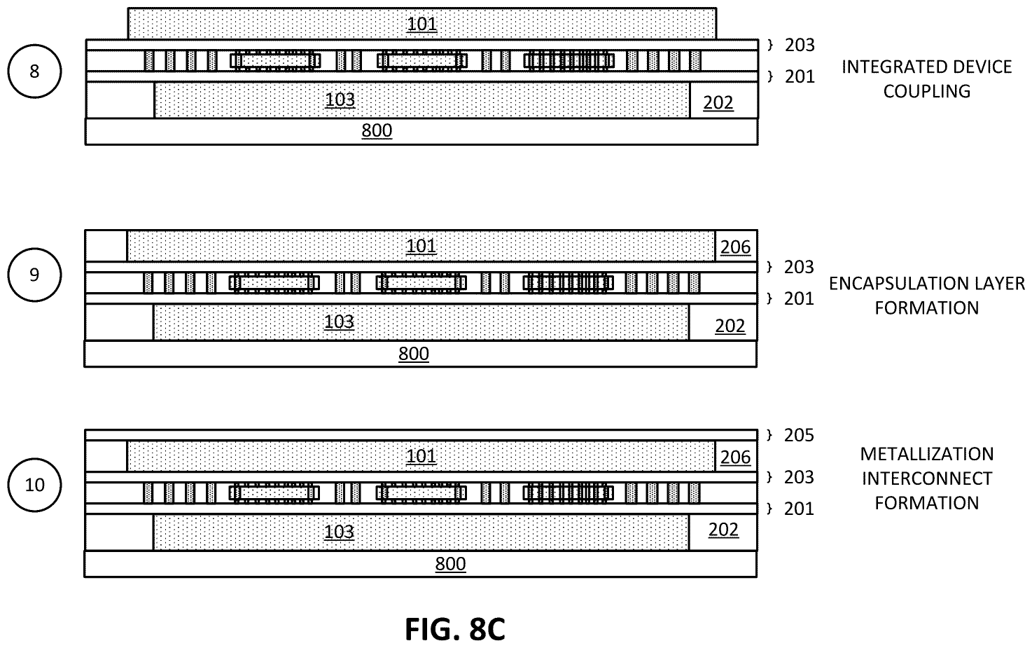

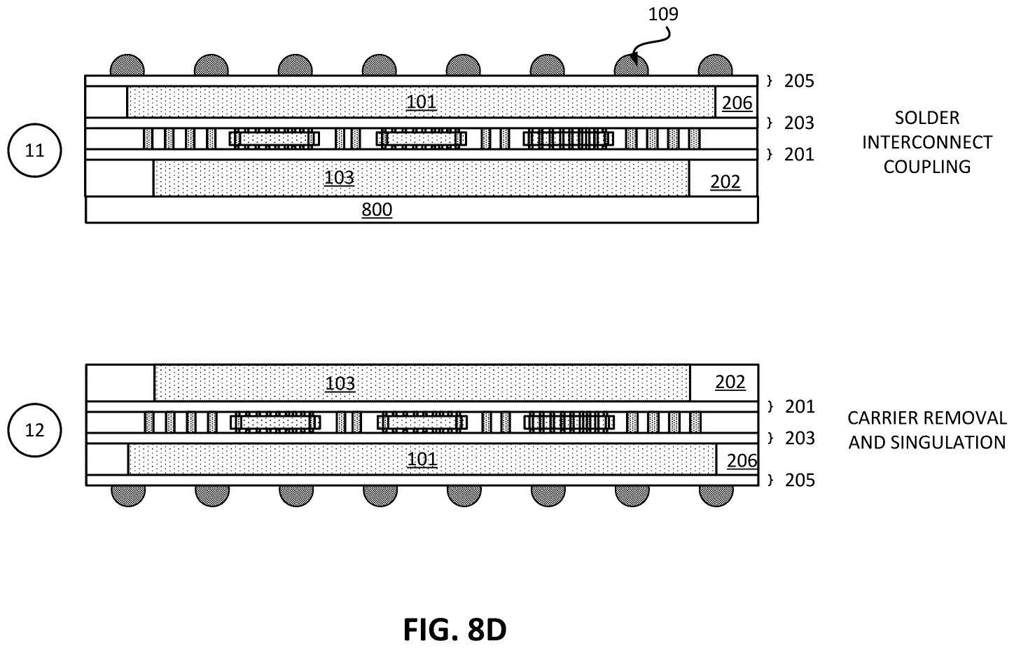

FIGS. 8A-8D illustrate an exemplary sequence for providing or fabricating a package with integrated devices and a passive device. In some implementations, the sequence of FIGS. 8A-8D may be used to provide or fabricate any of the packages described in the disclosure. In some implementations, the sequence of FIGS. 8A-8D may be used to provide or fabricate the package 200 described in the disclosure.

It should be noted that the sequence of FIGS. 8A-8D may combine one or more stages in order to simplify and/or clarify the sequence for providing or fabricating a package. In some implementations, the order of the processes may be changed or modified. In some implementations, one or more of processes may be replaced or substituted without departing from the spirit of the disclosure. Different implementations may fabricate a package differently.

Stage 1, as shown in FIG. 8A, illustrates a state after an integrated device 103 and a carrier 800 are provided. The integrated device 103 may be placed and coupled to the carrier 800 through an adhesive (not shown). The back side of the integrated device 103 may be coupled to the carrier 800. The carrier 800 may include tape.

Stage 2 illustrates a state after an encapsulation layer 202 is formed over the carrier 800. The encapsulation layer 202 may be coupled to the carrier and the integrated device 103. The encapsulation layer 202 may be formed over the front side of the integrated device 103 and portions of the encapsulation layer 202 may be removed (e.g., grinded off, polished). The encapsulation layer 202 may be provided by using a compression and transfer molding process, a sheet molding process, or a liquid molding process.

Stage 3 illustrates a state after a metallization portion 201 is formed and coupled to the front side of the integrated device 103. The metallization portion 201 may include at least one dielectric layer 210 and a plurality of metallization interconnects 212. The metallization portion 201 may include a redistribution portion. The plurality of metallization interconnects 112 may include a plurality of redistribution interconnects. The metallization portion 201 may touch the front side of the integrated device 103. The plurality of metallization interconnects 112 may be coupled to the plurality of pad interconnects of the integrated device 103. A lamination process and a plating process may be used to form the metallization portion 201. An example of fabricating a metallization portion is described below in at least FIGS. 10A-10B.

Stage 4 illustrates a state after a plurality of post interconnects 104 are formed and coupled to the metallization portion 201. The plurality of post interconnects 104 may be coupled to and touching the plurality of metallization interconnects 112. A plating process may be used to form the plurality of post interconnects 140. In the event there is no metallization portion 201, the plurality of post interconnects 104 may be formed and coupled to the front side of the integrated device 103.

Stage 5, as shown in FIG. 8B, illustrates a state after the passive device 105a, the passive device 105b, and the interposer 107 are placed and coupled to the metallization portion 201. The passive device 105a may be coupled to the metallization portion 201 through a plurality of solder interconnects 106a, using a solder reflow process. The passive device 105b may be coupled to the metallization portion 201 through a plurality of solder interconnects 106b, using a solder reflow process. The interposer 107 may be coupled to the metallization portion 201 through a plurality of solder interconnects 106c, using a solder reflow process. In the event there is no metallization portion 201, the passive device 105a, the passive device 105b and/or the interposer 107 may be coupled to the front side of the integrated device 103, through a plurality of solder interconnects.

Stage 6 illustrates a state after an encapsulation layer 204 is formed over the metallization portion 303. The encapsulation layer 204 may be coupled to the metallization portion 303. The encapsulation layer 204 may be formed over the passive device 105a, the passive device 105b, the interposer 107 and the plurality of post interconnects 104 and portions of the encapsulation layer 204 may be removed (e.g., grinded off, polished). In some implementations, portions of the passive device 105a, portions of the passive device 105b, portions of the interposer 107 and/or portions of the plurality of post interconnects 104 may also be removed (e.g., grinded off). The encapsulation layer 204 may be provided by using a compression and transfer molding process, a sheet molding process, or a liquid molding process.

Stage 7 illustrates a state after a metallization portion 203 is formed and coupled to the passive device 105a, the passive device 105b, the interposer 107 and/or the plurality of post interconnects 104. The metallization portion 203 may include at least one dielectric layer 230 and a plurality of metallization interconnects 232. The metallization portion 203 may include a redistribution portion. The plurality of metallization interconnects 232 may include a plurality of redistribution interconnects. The metallization portion 203 may touch the passive device 105a, the passive device 105b, the interposer 107 and/or the plurality of post interconnects 104. There may or may not be solder interconnects between (i) the metallization portion 203 and (ii) the passive device 105a, the passive device 105b, the interposer 107 and/or the plurality of post interconnects 104. A lamination process and a plating process may be used to form the metallization portion 203. An example of fabricating a metallization portion is described below in at least FIGS. 10A-10B.

Stage 8, as shown in FIG. 8C, illustrates a state after the integrated device 101 is placed and coupled to the metallization portion 203. The back side of the integrated device 101 may be coupled to the metallization portion 203. The back side of the integrated device 101 may face and/or point in the direction of a surface of the metallization portion 203. In some implementations, the back side of the integrated device 101 may be closer to the metallization portion 203 than the front side of the integrated device 101 is to the metallization portion 203. A solder reflow process may be used to couple the integrated device 101 to the metallization portion 203 through at least a plurality of solder interconnects (not shown). The plurality of solder interconnects may be coupled to the plurality of through substrate vias of the integrated device 101 and the plurality of metallization interconnects 232 of the metallization portion 203. In the event there is no metallization portion 203, the integrated device 101 (e.g., back side of the integrated device 101) may be coupled to the passive device 105a, the passive device 105b, the interposer 107 and the plurality of post interconnects 104 through a plurality of solder interconnects, using a solder reflow process.

Stage 9 illustrates a state after an encapsulation layer 206 is formed over the metallization portion 203 and the integrated device 101. The encapsulation layer 206 may be coupled to the metallization portion 203 and the integrated device 101. The encapsulation layer 206 may be provided by using a compression and transfer molding process, a sheet molding process, or a liquid molding process. In some implementations, portions of the encapsulation layer 206 may be removed (e.g., thinned, grinded off).

Stage 10 illustrates a state after a metallization portion 205 is formed and coupled to the front side of the integrated device 101. The metallization portion 305 may include at least one dielectric layer 250 and a plurality of metallization interconnects 252. The metallization portion 205 may include a redistribution portion. The plurality of metallization interconnects 252 may include a plurality of redistribution interconnects. The metallization portion 205 may touch the front side of the integrated device 101. The plurality of metallization interconnects 252 may be coupled to the plurality of pad interconnects of the integrated device 101. A lamination process and a plating process may be used to form the metallization portion 205. An example of fabricating a metallization portion is described below in at least FIGS. 10A-10B.

Stage 11, as shown in FIG. 8D, illustrates a state after the plurality of solder interconnects 109 are coupled to the metallization portion 205. A solder reflow process may be used to couple the plurality of solder interconnects 109 to the plurality of metallization interconnects 252 of the metallization portion 205. In the event there is no metallization portion 205, the plurality of solder interconnects 109 may be coupled to the integrated device 101, using a solder reflow process.

Stage 12 illustrates a state after the carrier 800 is decoupled from the integrated device 103 and the encapsulation layer 202. The carrier 800 may be detached and/or removed from the integrated device 103 and/or the encapsulation layer 202. Stage 12 illustrates an example of the package 200.

### Exemplary Flow Diagram of a Method for Fabricating a Package Comprising Integrated Devices and a Passive Device

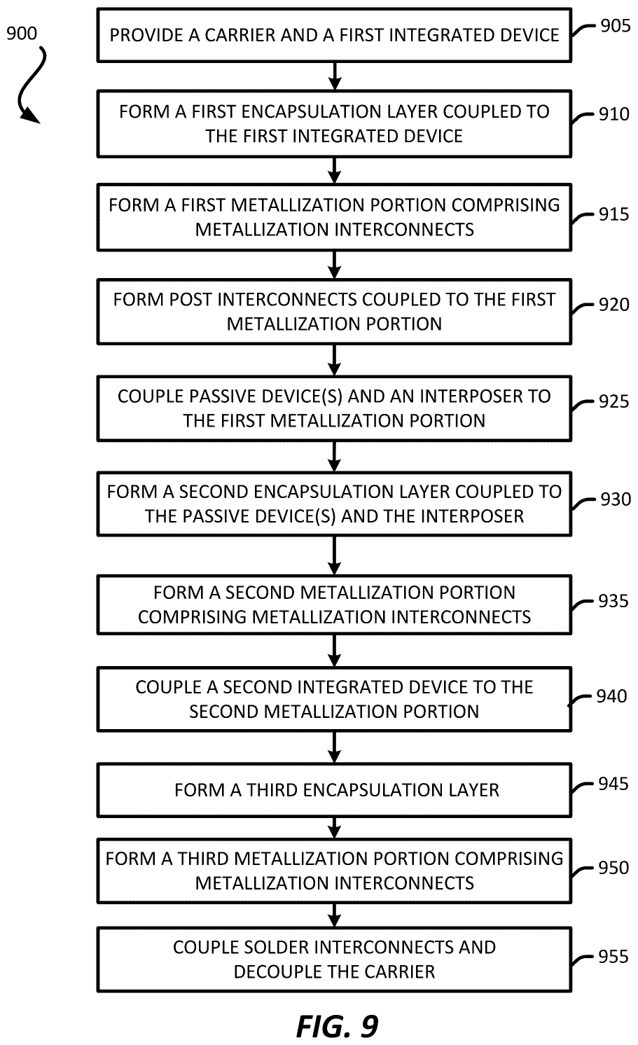

In some implementations, fabricating a package includes several processes. FIG. 9 illustrates an exemplary flow diagram of a method 900 for providing or fabricating a package with integrated devices and a passive device. In some implementations, the method 900 of FIG. 9 may be used to provide or fabricate the package 200.

It should be noted that the method 900 of FIG. 9 may combine one or more stages and/or sequences in order to simplify and/or clarify the method for providing or fabricating a package. In some implementations, the order of the processes may be changed or modified. In some implementations, one or more of processes may be replaced or substituted without departing from the spirit of the disclosure. Different implementations may fabricate a package differently.

The method provides (at 905) a carrier and a first integrated device. Stage 1 of FIG. 8A, illustrates and describes an example of a state after an integrated device 103 and a carrier 800 are provided. The integrated device 103 may be placed and coupled to the carrier 800 through an adhesive (not shown). The back side of the integrated device 103 may be coupled to the carrier 800. The carrier 800 may include tape.

The method forms (at 910) a first encapsulation layer that is coupled to the first integrated device. Stage 2 of FIG. 8A, illustrates and describes an example of a state after an encapsulation layer 202 is formed over the carrier 800. The encapsulation layer 202 may be coupled to the carrier and the integrated device 103. The encapsulation layer 202 may be formed over the front side of the integrated device 103 and portions of the encapsulation layer 202 may be removed (e.g., grinded off, polished). The encapsulation layer 202 may be provided by using a compression and transfer molding process, a sheet molding process, or a liquid molding process.

The method forms (at 915) a first metallization portion that is coupled to the first integrated device. Stage 3 of FIG. 8A, illustrates and describes an example of a state after a metallization portion 201 is formed and coupled to the front side of the integrated device 103. The metallization portion 201 may include at least one dielectric layer 210 and a plurality of metallization interconnects 212. The metallization portion 201 may include a redistribution portion. The plurality of metallization interconnects 112 may include a plurality of redistribution interconnects. The metallization portion 201 may touch the front side of the integrated device 103. The plurality of metallization interconnects 112 may be coupled to the plurality of pad interconnects of the integrated device 103. A lamination process and a plating process may be used to form the metallization portion 201. An example of fabricating a metallization portion is described below in at least FIGS. 10A-10B.

The method forms (at 920) a plurality of post interconnects that are coupled to the first metallization portion. Stage 4 of FIG. 8A, illustrates and describes an example of a state after a plurality of post interconnects 104 are formed and coupled to the metallization portion 201. The plurality of post interconnects 104 may be coupled to and touching the plurality of metallization interconnects 112. A plating process may be used to form the plurality of post interconnects 140. In the event there is no metallization portion 201, the plurality of post interconnects 104 may be formed and coupled to the front side of the integrated device 103.

The method places and couples (at 925) passive devices and an interposer to the first metallization portion. Stage 5 of FIG. 8B, illustrates and describes an example of a state after the passive device 105a, the passive device 105b, and the interposer 107 are placed and coupled to the metallization portion 201. The passive device 105a may be coupled to the metallization portion 201 through a plurality of solder interconnects 106a, using a solder reflow process. The passive device 105b may be coupled to the metallization portion 201 through a plurality of solder interconnects 106b, using a solder reflow process. The interposer 107 may be coupled to the metallization portion 201 through a plurality of solder interconnects 106c, using a solder reflow process. In the event there is no metallization portion 201, the passive device 105a, the passive device 105b and/or the interposer 107 may be coupled to the front side of the integrated device 103, through a plurality of solder interconnects.

The method forms (at 930) a second encapsulation layer that is coupled to first metallization portion. Stage 6 of FIG. 8B, illustrates and describes an example of a state after an encapsulation layer 204 is formed over the metallization portion 303. The encapsulation layer 204 may be coupled to the metallization portion 303. The encapsulation layer 204 may be formed over the passive device 105a, the passive device 105b, the interposer 107 and the plurality of post interconnects 104 and portions of the encapsulation layer 204 may be removed (e.g., grinded off, polished). In some implementations, portions of the passive device 105a, portions of the passive device 105b, portions of the interposer 107 and/or portions of the plurality of post interconnects 104 may also be removed (e.g., grinded off). The encapsulation layer 204 may be provided by using a compression and transfer molding process, a sheet molding process, or a liquid molding process.

The method forms (at 935) a second metallization portion that is coupled to the passive devices, the interposer and/or the plurality of post interconnects. Stage 7 of FIG. 8B, illustrates and describes a state after a metallization portion 203 is formed and coupled to the passive device 105a, the passive device 105b, the interposer 107 and/or the plurality of post interconnects 104. The metallization portion 203 may include at least one dielectric layer 230 and a plurality of metallization interconnects 232. The metallization portion 203 may include a redistribution portion. The plurality of metallization interconnects 232 may include a plurality of redistribution interconnects. The metallization portion 203 may touch the passive device 105a, the passive device 105b, the interposer 107 and/or the plurality of post interconnects 104. There may or may not be solder interconnects between (i) the metallization portion 203 and (ii) the passive device 105a, the passive device 105b, the interposer 107 and/or the plurality of post interconnects 104. A lamination process and a plating process may be used to form the metallization portion 203. An example of fabricating a metallization portion is described below in at least FIGS. 10A-10B.

The method couples (at 940) a second integrated device to the second metallization portion. Stage 8 of FIG. 8C, illustrates and describes an example of a state after the integrated device 101 is placed and coupled to the metallization portion 203. The back side of the integrated device 101 may be coupled to the metallization portion 203. The back side of the integrated device 101 may face and/or point in the direction of a surface of the metallization portion 203. In some implementations, the back side of the integrated device 101 may be closer to the metallization portion 203 than the front side of the integrated device 101 is to the metallization portion 203. A solder reflow process may be used to couple the integrated device 101 to the metallization portion 203 through at least a plurality of solder interconnects (not shown). The plurality of solder interconnects may be coupled to the plurality of through substrate vias of the integrated device 101 and the plurality of metallization interconnects 232 of the metallization portion 203. In the event there is no metallization portion 203, the integrated device 101 (e.g., back side of the integrated device 101) may be coupled to the passive device 105a, the passive device 105b, the interposer 107 and the plurality of post interconnects 104 through a plurality of solder interconnects, using a solder reflow process.

The method forms (at 945) a third encapsulation layer that is coupled to the second integrated device and the second metallization portion. Stage 9 of FIG. 8C, illustrates and describes an example of a state after an encapsulation layer 206 is formed over the metallization portion 203 and the integrated device 101. The encapsulation layer 206 may be coupled to the metallization portion 203 and the integrated device 101. The encapsulation layer 206 may be provided by using a compression and transfer molding process, a sheet molding process, or a liquid molding process. In some implementations, portions of the encapsulation layer 206 may be removed (e.g., thinned, grinded off).

The method forms (at 950) a third metallization portion is coupled to the second integrated device. Stage 10 of FIG. 8C, illustrates and describes an example of a state after a metallization portion 205 is formed and coupled to the front side of the integrated device 101. The metallization portion 305 may include at least one dielectric layer 250 and a plurality of metallization interconnects 252. The metallization portion 205 may include a redistribution portion. The plurality of metallization interconnects 252 may include a plurality of redistribution interconnects. The metallization portion 205 may touch the front side of the integrated device 101. The plurality of metallization interconnects 252 may be coupled to the plurality of pad interconnects of the integrated device 101. A lamination process and a plating process may be used to form the metallization portion 205. An example of fabricating a metallization portion is described below in at least FIGS. 10A-10B.

The method couples (at 955) a plurality of solder interconnects to the third metallization portion. Stage 11 of FIG. 8D, illustrates and describes an example of a state after the plurality of solder interconnects 109 are coupled to the metallization portion 205. A solder reflow process may be used to couple the plurality of solder interconnects 109 to the plurality of metallization interconnects 252 of the metallization portion 205. In the event there is no metallization portion 205, the plurality of solder interconnects 109 may be coupled to the integrated device 101, using a solder reflow process.

The method also decouples (at 955) the carrier from the first integrated device. Stage 12 of FIG. 8D, illustrates and describes an example of a state after the carrier 800 is decoupled from the integrated device 103 and the encapsulation layer 202. The carrier 800 may be detached and/or removed from the integrated device 103 and/or the encapsulation layer 202. Stage 12 illustrates an example of the package 200.

It is noted that the use and/or labeling of the first integrated device and the second integrated device is arbitrary. Any of the integrated devices may be the first integrated device and/or the second integrated device. It is noted that the use and/or labeling of the first metallization portion, the second metallization portion and the third metallization portion is arbitrary. Any of the metallization portions may be the first metallization portion, the second metallization portion and/or the third metallization portion. It is noted that the use and/or labeling of the first encapsulation layer, the second encapsulation layer and the third encapsulation layer is arbitrary. Any of the encapsulation layers may be the first encapsulation layer, the second encapsulation layer and/or the third encapsulation layer.

### Exemplary Sequence for Fabricating a Metallization Portion

In some implementations, fabricating a metallization portion includes several processes. FIGS. 10A-10B illustrate an exemplary sequence for providing or fabricating a metallization portion. In some implementations, the sequence of FIGS. 10A-10B may be used to provide or fabricate the metallization portion 201. However, the process of FIGS. 10A-10B may be used to fabricate any of the metallization portions (e.g., 203, 205, 301, 303, 305) described in the disclosure.

It should be noted that the sequence of FIGS. 10A-10B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 10A, illustrates a state after a carrier 1002, an integrated device 101 and an encapsulation layer 1006 are provided and/or formed.

Stage 2 illustrates a state after a dielectric layer 1010 is formed over the integrated device 101 and the encapsulation layer 1006. The dielectric layer 1010 may include a plurality of openings 1011. A deposition and/or lamination process may be used to form the dielectric layer 1010. The dielectric layer 1010 may include prepreg. The plurality of openings 1011 may be formed using an etching process (e.g., photo etching process) or laser process. For example, an exposure and development process may be used to form the plurality of openings 1011.

Stage 3 illustrates a state after a plurality of interconnects 1012 are formed in and over the dielectric layer 1010, including in and over the plurality of openings 1011. For example, via interconnects, pad interconnects and/or trace interconnects may be formed. A plating process may be used to form the interconnects. Stage 3 illustrates that some portions of the interconnects 1012 may have a U-shape or a V-shape. The terms “U-shape” and “V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect).

Stage 4, as shown in FIG. 10B, illustrates a state after a dielectric layer 1020 is formed over the dielectric layer 1010. The dielectric layer 1020 may include a plurality of openings 1021. A deposition and/or lamination process may be used to form the dielectric layer 1020. The dielectric layer 1020 may include prepreg. The plurality of openings 1021 may be formed using an etching process (e.g., photo etching process) or laser process. For example, an exposure and development process may be used to form the plurality of openings 1021.

Stage 5 illustrates a state after a plurality of interconnects 1022 are formed in and over the dielectric layer 1020, including in and over the plurality of openings 1021. For example, via interconnects, pad interconnects and/or trace interconnects may be formed. A plating process may be used to form the interconnects. Stage 5 illustrates that some portions of the interconnects 1022 may have a U-shape or a V-shape. The terms “U-shape” and “V-shape” shall be interchangeable. The terms “U-shape” and “V-shape” may refer to the side profile shape of the interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). The plurality of interconnects 1012 and/or the plurality of interconnects 1022 may represent a plurality of metallization interconnects (e.g., 212, 232, 252, 312, 332, 352).

It is noted that the process of forming the dielectric layers, the plurality of openings and the plurality of interconnects may be iteratively performed to form additional metal layers in the metallization portions.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

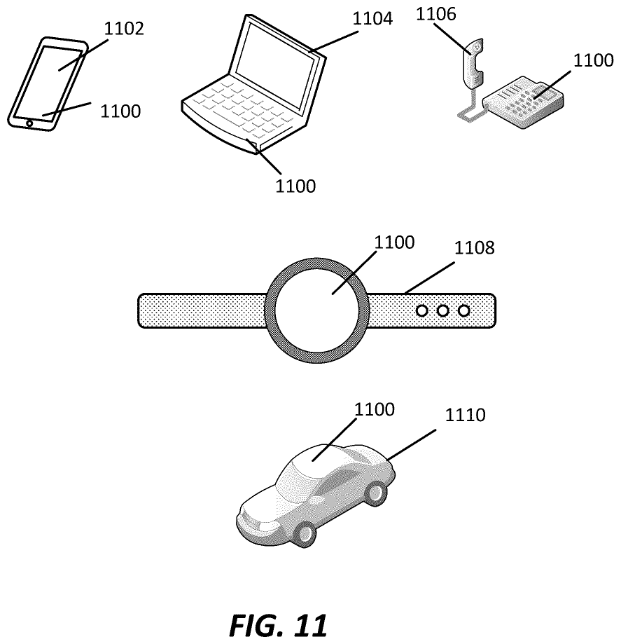

FIG. 11 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1102, a laptop computer device 1104, a fixed location terminal device 1106, a wearable device 1108, or automotive vehicle 1110 may include a device 1100 as described herein. The device 1100 may be, for example, any of the devices and/or integrated circuit (IC) packages described herein. The devices 1102, 1104, 1106 and 1108 and the vehicle 1110 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-5, 6A-6D, 7, 8A-8D, 9, 10A-10B and/or 11 may be rearranged and/or combined into a single component, process, feature or function or embodied in several components, processes, or functions. Additional elements, components, processes, and/or functions may also be added without departing from the disclosure. It should also be noted FIGS. 1-5, 6A-6D, 7, 8A-8D, 9, 10A-10B and/or 11 and its corresponding description in the present disclosure is not limited to dies and/or ICs. In some implementations, FIGS. 1-5, 6A-6D, 7, 8A-8D, 9, 10A-10B and/or 11 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object that is coupled to another object may be coupled to at least part of the another object. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components. An object that “faces” and/or “points to” another object may mean that a surface (e.g., outer surface) of the object may be face and/or point to in a direction towards the other object. An object that “faces” another object may mean that a surface (e.g., outer surface) of the object may be pointed in and/or directed in the direction of the other object and/or towards the other object. For example, an object A that has a first surface (e.g., first outer surface) that faces the second surface (e.g., second outer surface) of an object B, may mean that the first surface of object A may be pointed in the direction of (e.g., direction towards) the second surface of the object B. This may be the case even if there is one or more components between the first surface of object A and the second surface of object B. Thus, for example, if object A is coupled to object C, and object B is coupled to object C such that object C is between object A and object B, it may be possible that a surface of object A may be pointed in the direction of (e.g., points in a direction towards) object B, despite the presence of object C between object A and object B. The direction in which an object faces and/or points towards may be a direction that is perpendicular to a surface (e.g., outer surface) of the object. A front side of an object that faces and/or points in a direction of another object, may mean a surface of the front side faces and/or points in a direction of another object.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A package comprising a first integrated device; an interposer coupled to the first integrated device; a passive device coupled to the first integrated device; a plurality of post interconnects coupled to the first integrated device; a second integrated device coupled to the interposer, the passive device and the plurality of post interconnects; and an encapsulation layer located between the first integrated device and the second integrated device.

Aspect 2: The package of aspect 1, wherein the encapsulation layer at least partially encapsulates the interposer, the passive device, and the plurality of post interconnects.

Aspect 3: The package of aspects 1 through 2, wherein the passive device includes a deep trench capacitor.

Aspect 4: The package of aspects 1 through 3, wherein the interposer comprises a silicon substrate; and a plurality of interposer interconnects.

Aspect 5: The package of aspects 1 through 4, wherein the first integrated device comprises a first front side and a first back side; and wherein the second integrated device comprises a second front side and a second back side.

Aspect 6: The package of aspect 5, wherein the first front side of the first integrated device is pointed in a direction towards the second integrated device.

Aspect 7: The package of aspect 5, wherein the first front side of the first integrated device is pointed in a direction towards the second back side of the second integrated device.

Aspect 8: The package of aspect 5, wherein the first front side of the first integrated device is pointed in a direction towards the second front side of the second integrated device.

Aspect 9: The package of aspects 1 through 8, further comprising a first metallization portion located between the first integrated device and interposer.

Aspect 10: The package of aspect 9, further comprising a second metallization portion located between the second integrated device and interposer.

Aspect 11: The package of aspect 10, wherein the encapsulation layer is located between the first metallization portion and the second metallization portion.

Aspect 12: The package of aspects 10 through 11, further comprising a third metallization portion coupled to the second integrated device.

Aspect 13: The package of aspects 10 through 12, wherein the first metallization portion comprises: at least one first dielectric layer; and a first plurality of metallization interconnects; wherein the second metallization portion comprises: at least one second dielectric layer; and a second plurality of metallization interconnects.

Aspect 14: The package of aspects 10 through 13, wherein the first integrated device is coupled to the interposer and the passive device through at least the first metallization portion, and wherein the second integrated device is coupled to the interposer and the passive device through at least the second metallization portion.

Aspect 15: The package of aspects 1 through 8, further comprising a first metallization portion located between the second integrated device and interposer.

Aspect 16: The package of aspects 1 through 15, wherein the first integrated device and/or the second integrated device includes a plurality of through substrate vias.

Aspect 17: The package of aspects 1 through 8, further comprising: a first metallization portion coupled to a front side of the first integrated device; a second metallization portion coupled to a back side of the first integrated device; and a third metallization portion coupled to the second integrated device.

Aspect 18: The package of aspect 17, further comprising: a second encapsulation layer located between the first metallization portion and the second metallization portion; and a third encapsulation layer coupled to the third metallization portion, and wherein the encapsulation layer is located between the second metallization portion and the third metallization portion.

Aspect 19: A method for fabricating a package. The method provides a first integrated device. The method forms a first encapsulation layer that is coupled to the first integrated device. The method forms a first metallization portion that is coupled to the first integrated device. The method couples an interposer to the first metallization portion. The method couples a passive device to the first metallization portion. The method forms a plurality of post interconnects that are coupled to the first metallization portion. The method forms a second encapsulation layer that is coupled to the first metallization portion, the interposer, the passive device and the plurality of post interconnects. The method forms a second metallization portion that is coupled to the interposer, the passive device and the plurality of post interconnects. The method couples a second integrated device to the second metallization portion.

Aspect 20: The method of aspect 19, further comprises forming a third encapsulation layer that is coupled to the second integrated device; and forming a third metallization portion that is coupled to the second integrated device.

Aspect 21: The method of aspect 20, wherein the third metallization portion is coupled to a front side of the second integrated device.

Aspect 22: The method of aspects 19 through 21, wherein the second metallization portion is coupled to a back side of the second integrated device.

Aspect 23: The method of aspects 19 through 21, wherein the first metallization portion is coupled to a front side of the first integrated device.

Aspect 24: The method of aspects 19 through 21, wherein the first metallization portion is coupled to a back side of the first integrated device.

Aspect 25: The method of aspects 19 through 21, wherein the first integrated device is located between the first metallization portion and the second metallization portion.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first integrated device;
an interposer coupled to the first integrated device;
a passive device coupled to the first integrated device;
a plurality of post interconnects coupled to the first integrated device;
a second integrated device coupled to the interposer, the passive device and the plurality of post interconnects; and
an encapsulation layer located between the first integrated device and the second integrated device.

2. The package of claim 1, wherein the encapsulation layer at least partially encapsulates the interposer, the passive device, and the plurality of post interconnects.

3. The package of claim 1, wherein the passive device includes a deep trench capacitor.

4. The package of claim 1, wherein the interposer comprises:
a silicon substrate; and
a plurality of interposer interconnects.

5. The package of claim 1,
wherein the first integrated device comprises a first front side and a first back side; and
wherein the second integrated device comprises a second front side and a second back side.

6. The package of claim 5, wherein the first front side of the first integrated device is pointed in a direction towards the second integrated device.

7. The package of claim 5, wherein the first front side of the first integrated device is pointed in a direction towards the second back side of the second integrated device.

8. The package of claim 5, wherein the first front side of the first integrated device is pointed in a direction towards the second front side of the second integrated device.

9. The package of claim 1, further comprising a first metallization portion located between the first integrated device and the interposer.

10. The package of claim 9, further comprising a second metallization portion located between the second integrated device and the interposer.

11. The package of claim 10, wherein the encapsulation layer is located between the first metallization portion and the second metallization portion.

12. The package of claim 10, further comprising a third metallization portion coupled to the second integrated device.

13. The package of claim 10,
wherein the first metallization portion comprises:
at least one first dielectric layer; and
a first plurality of metallization interconnects; and
wherein the second metallization portion comprises:
at least one second dielectric layer; and
a second plurality of metallization interconnects.

14. The package of claim 10,
wherein the first integrated device is coupled to the interposer and the passive device through at least the first metallization portion, and
wherein the second integrated device is coupled to the interposer and the passive device through at least the second metallization portion.

15. The package of claim 1, further comprising a first metallization portion located between the second integrated device and the interposer.

16. The package of claim 1, wherein the first integrated device and/or the second integrated device includes a plurality of through substrate vias.

17. The package of claim 1, further comprising:
a first metallization portion coupled to a front side of the first integrated device;
a second metallization portion coupled to a back side of the first integrated device; and
a third metallization portion coupled to the second integrated device.

18. The package of claim 17, further comprising:
a second encapsulation layer located between the first metallization portion and the second metallization portion; and
a third encapsulation layer coupled to the third metallization portion,
wherein the encapsulation layer is located between the second metallization portion and the third metallization portion.

19. A method for fabricating a package, comprising:
providing a first integrated device;
forming a first encapsulation layer that is coupled to the first integrated device;
forming a first metallization portion that is coupled to the first integrated device;
coupling an interposer to the first metallization portion;
coupling a passive device to the first metallization portion;
forming a plurality of post interconnects that are coupled to the first metallization portion;
forming a second encapsulation layer that is coupled to the first metallization portion, the interposer, the passive device and the plurality of post interconnects;
forming a second metallization portion that is coupled to the interposer, the passive device and the plurality of post interconnects; and
coupling a second integrated device to the second metallization portion.

20. The method of claim 19, further comprising:
forming a third encapsulation layer that is coupled to the second integrated device; and
forming a third metallization portion that is coupled to the second integrated device.

21. The method of claim 20, wherein the third metallization portion is coupled to a front side of the second integrated device.

22. The method of claim 19, wherein the second metallization portion is coupled to a back side of the second integrated device.

23. The method of claim 19, wherein the first metallization portion is coupled to a front side of the first integrated device.

24. The method of claim 19, wherein the first metallization portion is coupled to a back side of the first integrated device.

25. The method of claim 19, wherein the first integrated device is located between the first metallization portion and the second metallization portion.
